(19) United States
(12) Patent Application Publication
(10) Pub. No.: US 2024/0196753 A1
(43) Pub. Date: Jun. 13, 2024

(54) METHODS OF FORMING ACOUSTIC RESONATOR DEVICE WAFERS INTEGRATED WITH ELECTRONIC SEMICONDUCTOR SWITCHING DEVICE WAFERS USING A WAFER TRANSFER PROCESS AND RELATED STRUCTURES

(71) Applicant: Akoustis, Inc., Huntersville, NC (US)

(72) Inventors: Kamran Cheema, Apopka, FL (US); Abhay Saranswarup Kochhar, Charlotte, NC (US); Ramakrishna Vetury, Charlotte, NC (US); Daeho Kim, Cornelius, NC (US)

(21) Appl. No.: 18/065,538

(22) Filed: Dec. 13, 2022

(51) Int. Cl. H10N 39/00; H03H 3/02; H03H 9/05; H03H 9/17

(52) U.S. Cl. CPC H10N 39/00; H03H 3/02; H03H 9/0547; H03H 9/173; H03H 9/175; H03H 2003/021; H03H 2003/025

(57) ABSTRACT

A method of forming a MEMS/integrated circuit structure can include forming a piezoelectric layer on a surface of a growth substrate, forming a first electrode on the piezoelectric layer, forming a support layer on the piezoelectric layer and the first electrode, bonding an upper surface of the support layer to an upper surface of an integrated circuit wafer to form a bonded interface therebetween, wherein the integrated circuit wafer includes a substrate, a plurality of first layers on the substrate, the plurality of first layers forming a front-end of line portion of the integrated circuit wafer having electronic semiconductor switching devices therein, and a plurality of second layers forming a back-end of line portion of the integrated circuit wafer including ohmic conductors ohmically coupling regions of the electronic semiconductor switching devices to an outer one of the second layers of the integrated circuit wafer positioned opposite the electronic semiconductor switching devices.

### FIELD

The present invention relates to packaging of integrated circuits in general, and more particularly, to wafer level packaging for integrated circuits.

### BACKGROUND

Integrated circuits can be processed at the wafer level to provide numerous layers that can be defined as being either included in the Front End of Line or the Back End of Line in the process. The processed integrated circuit wafers can then be diced to provide singulated integrated circuits. These singulated circuits can be packaged to provide packaged integrated circuit devices, which can used to create an electronic device, such as mobile telephone.

### SUMMARY

Embodiments according to the inventive concept can provide methods of forming acoustic resonator device wafers integrated with electronic semiconductor switching device wafers using a wafer transfer process and related structures. Pursuant to these embodiments, a method of forming a MEMS/integrated circuit structure can include forming a piezoelectric layer on a surface of a growth substrate, forming a first electrode on the piezoelectric layer, forming a support layer on the piezoelectric layer and the first electrode, bonding an upper surface of the support layer to an upper surface of an integrated circuit wafer to form a bonded interface therebetween, wherein the integrated circuit wafer includes a substrate, a plurality of first layers on the substrate, the plurality of first layers forming a front-end of line portion of the integrated circuit wafer having electronic semiconductor switching devices therein, and a plurality of second layers forming a back-end of line portion of the integrated circuit wafer including ohmic conductors ohmically coupling regions of the electronic semiconductor switching devices to an outer one of the second layers of the integrated circuit wafer positioned opposite the electronic semiconductor switching devices.

### BRIEF DESCRIPTION OF THE DRAWINGS

FIG. 1 is a cross-sectional diagram showing an acoustic resonator device wafer bonded to an integrated circuit wafer in some embodiments according to the inventive concept.

FIGS. 2A-2C through FIGS. 19A-19C, and FIG. 8D illustrate methods of bonding acoustic resonator device wafers to integrated circuit wafers where the respective devices therein can be coupled together as part of the transfer process described herein to provide wafers that include integrated devices using a sacrificial layer in some embodiments according to the inventive concept.

FIGS. 20A-20C through FIGS. 35A-35C illustrate methods of bonding acoustic resonator device wafers (having a multilayer mirror structure) to integrated circuit wafers where the respective devices therein can be coupled together as part of the transfer process described herein to provide wafers that include integrated devices using a sacrificial layer in some embodiments according to the inventive concept.

FIGS. 36-38 are cross-sectional diagrams illustrating methods of forming a plurality of acoustic resonator devices included in an acoustic resonator device wafer bonded to an integrated circuit wafer using the transfer process described herein in some embodiments according to the inventive concept.

FIG. 39 illustrates a cross-sectional diagram showing a GaN HEMT device that can be the electronic semiconductor switching device included in the FEOL portion of the integrated circuit wafer in some embodiments according to the inventive concept.

### DESCRIPTION OF EMBODIMENTS ACCORDING TO THE INVENTIVE CONCEPT

According to the present invention, techniques generally related to electronic devices are provided. More particularly, the present invention provides techniques related to methods of manufacture and structure for bulk acoustic wave resonator devices wafers and the devices included therein being bonded to integrated circuit wafers, and the like. Merely by way of example, embodiments according to the inventive concept are illustrated herein using a limited number of devices on a wafers. It will be understood, however, that the number of devices on the wafers may be more than that illustrated.

As appreciated by the present inventors, embodiments according to the inventive concept can provide a wafer with acoustic resonator devices thereon, bonded to a wafer that includes other electronic devices, such as active or passive devices. In some embodiments according to the inventive concept, a wafer can include electronic semiconductor switching devices, such as CMOS transistors, power MOSFET devices, IGBT devices, HEMT devices, such as GaN HEMT devices, resistive memory devices, such as phase change materials, magnetic memories, spintronics or the like. In some embodiments according to the inventive concept, the wafer with acoustic resonator devices thereon, integrated with (via bonding) to an integrated circuit wafer that includes any combination of the device types listed herein. In some embodiments according to the inventive concept, the wafer with acoustic resonator devices thereon can be bonded to a wafer that includes integrated passive devices such as resistive, inductive, or capacitive components as well as combinations of these components.

It will be understood, therefore that the acoustic resonator device wafer according to embodiments of the inventive concept can be coupled to a wafer that includes any type of switching device. Accordingly, in some embodiments according to the inventive concept, the acoustic resonator device wafer can be coupled to the integrated circuit wafer and the respective devices in the wafers can be coupled together as part of the present transfer process to provide bonded wafers that include those devices (including the electronic semiconductor switching devices and the acoustic resonator devices) operating as part of an integrated device.

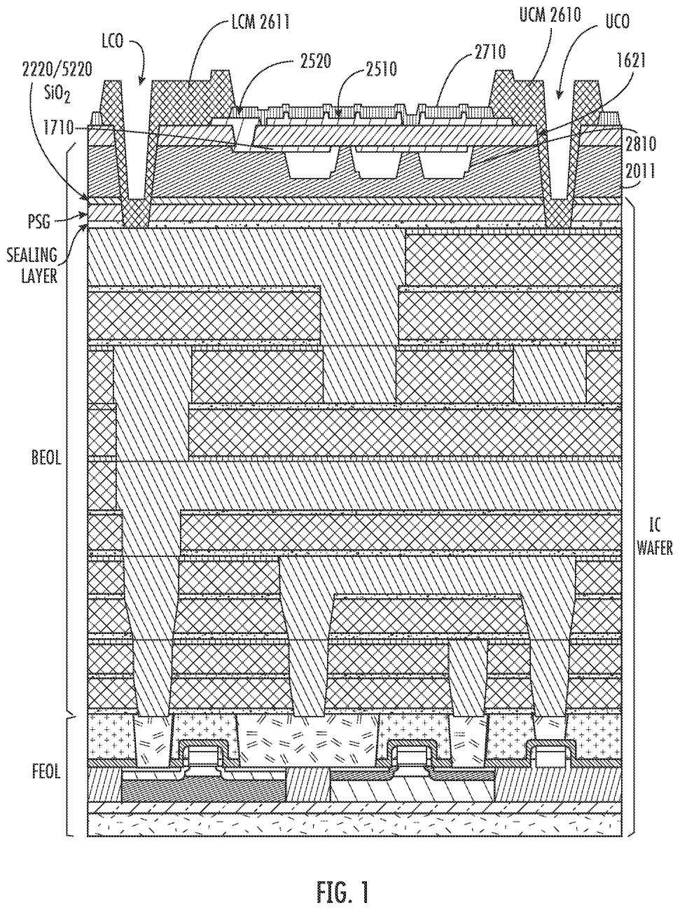

FIG. 1 is a cross-sectional diagram showing an acoustic resonator device wafer bonded to an integrated circuit wafer in some embodiments according to the inventive concept. According to FIG. 1, the acoustic resonator device wafer can include a plurality of piezoelectric resonator devices that can be coupled together to provide, for example, an acoustic resonator filter device. The piezoelectric resonator devices can include crystalline piezoelectric films 1621 and can be formed using the transfer process described herein to provide, for example, upper and lower electrodes 2510 and 1710 of the piezoelectric resonator devices, the shape of the electrodes (including energy confinement structures), resonator cavities, solid mounted mirror reflector structures etc. The upper and lower electrodes 2510 and 1710 can be covered by a passivation layer 2710. In some embodiments according to the invention, the crystalline piezoelectric film 1621 can overlie a resonator cavity 2810. The transfer process can also be used to form the interconnect to couple, for example, inputs and outputs of the acoustic resonator filter devices to the electronic semiconductor switching devices included in the integrated circuit wafer. In some embodiments. The piezoelectric films described herein can be a single crystalline piezoelectric films or crystalline piezoelectric films.

In particular, according to FIG. 1 the integrated circuit wafer can include a substrate (such as a Si, SiC, sapphire, or other material) on which the electronic semiconductor switching devices are formed. The electronic semiconductor switching devices are formed of a plurality of layers, such as semiconductor regions with implanted impurities to provide channel regions, source/drain regions, p type or n type wells, source/drain and gate contacts, insulators, as well as conductive vias to provide access to the contacts of the devices. These layers are referred to herein as a front end of line (FEOL) portion of the integrated circuit wafer which can provide the materials and operation of the switching devices.

As further shown in FIG. 1, the integrated circuit wafer includes a plurality of layers on the FEOL portion, which is referred to herein as a back end of line (BEOL) portion of the integrated circuit wafer. According to FIG. 1, the BEOL portion includes ohmic conductors (such as Cu1-Cu5 etc.) that can ohmically couple the regions of the electronic semiconductor switching devices to inner and outer layers of the BEOL. In particular, the ohmic conductors can include conductive vias and interconnect withing the layers and between layers. The ohmic conductors can be included in the outer layers of the BEOL portion that are proximate to the bonded interface where the integrated circuit wafer is bonded to the acoustic resonator device wafer.

As further shown in FIG. 1A, the integrated circuit wafer can also include a sealing layer, such as SiN, on the outermost layer of the BEOL portion and a PSG layer on the sealing layer. In some embodiments the acoustic resonator devices can be formed to include a SiO2 layer 5220/2220 on the support layer 2011 to promote the bonding of the acoustic resonator wafer to the integrated circuit wafer. In some embodiments, the sealing layer, the PSG, and the SiO2 layer can be formed in any combination on the acoustic resonator wafer or on the integrated circuit wafer.

As further shown in FIG. 1, the electrodes of the acoustic resonator devices can be coupled to the regions of the electronic semiconductor switching devices by the contacts UMC 2610 and LCM 2611 which extend into openings LCO and UCO in the acoustic resonator device wafer to the ohmic contacts included in the BEOL portion of the integrated circuit wafer which may be coupled to the regions of the electronic semiconductor switching devices included in the FEOL portion of the integrated circuit wafer. As further shown, the contacts UMC 2610 and LCM 2611 can be coupled to the upper and lower electrodes by contact metal 2520. Although the integrated circuit wafer is shown in FIG. 1 to include CMOS devices, it will be understood that any type of electronic semiconductor switching devices may be used.

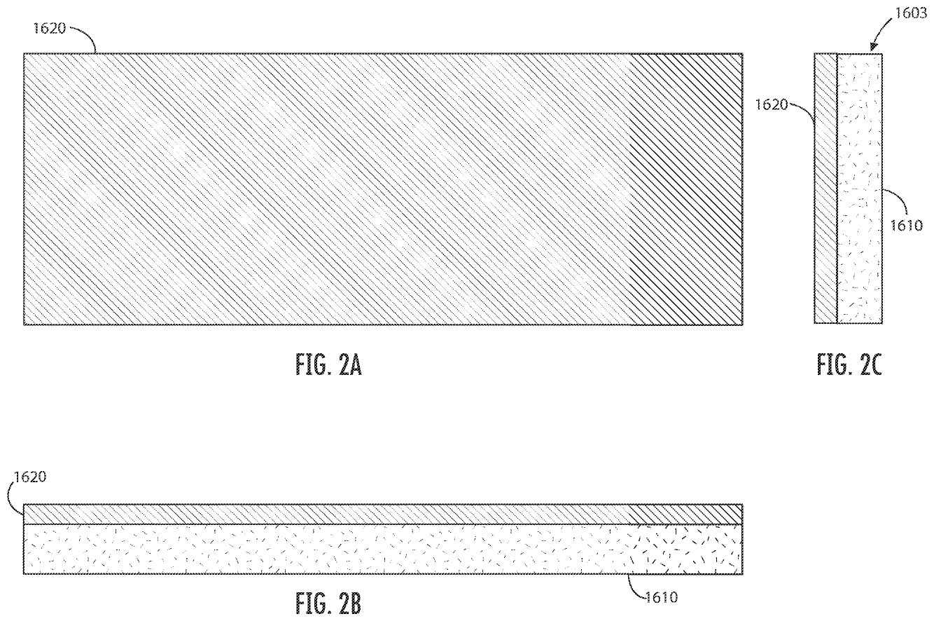

FIGS. 2A-2C through FIGS. 19A-19C illustrate methods of bonding acoustic resonator device wafers to integrated circuit wafers where the respective devices therein can be coupled together as part of the transfer process described herein to provide wafers that include integrated devices using a sacrificial layer. In these figure series described below, the “A” figures show diagrams illustrating top cross-sectional views of crystalline resonator devices included in an acoustic device wafer transferred to corresponding electronic semiconductor switch devices included in an integrated circuit wafer according to various embodiments of the present invention. The “B” figures show diagrams illustrating lengthwise cross-sectional views of the same devices in the “A” figures. Similarly, the “C” figures show diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

Accordingly, it will be understood that the devices shown are representative of a plurality of devices that are included in the wafer which can also be subjected to the transfer processes described herein. Further it will be understood that when a reference is made to, for example, a crystalline acoustic resonator device, that device may represent a portion of the wafer being processed. Still further, the “transfer process” refers to the formation of a portion of the acoustic resonator devices in the wafer followed by bonding those portions to the integrated circuit wafer followed by the completion of the acoustic resonator devices and the integration of the acoustic resonator devices with the electronic semiconductor switching devices in some embodiments.

FIGS. 2A-2C are diagrams illustrating various cross-sectional views of a crystalline acoustic resonator device and of method steps for the transfer process using a sacrificial layer for crystalline acoustic resonator devices according to an example of the present inventive concept. As shown, these figures illustrate methods of forming a piezoelectric film 1620 overlying a growth substrate 1610. In an example, the growth substrate 1610 can include silicon (S), silicon carbide (SiC), sapphire, or other like materials. The piezoelectric film 1620 can be an epitaxial or sputtered film including aluminum nitride (AlN), gallium nitride (GaN), Sc, In or other like materials. Additionally, this piezoelectric substrate can be subjected to a thickness trim.

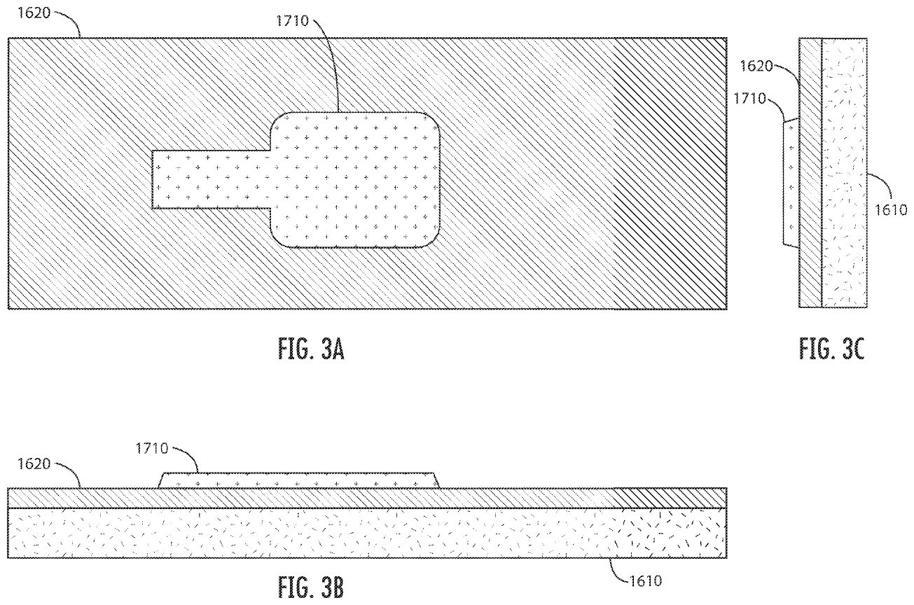

FIGS. 3A-3C are diagrams illustrating various cross-sectional views of a crystalline acoustic resonator device and of method steps for the transfer process using a sacrificial layer for crystalline acoustic resonator devices according to an example of the present inventive concept. As shown, these figures illustrate methods of forming a first electrode 1710 overlying the surface region of the piezoelectric film 1620. In an example, the first electrode 1710 can include molybdenum (Mo), ruthenium (Ru), tungsten (W), or other like materials. In a specific example, the first electrode 1710 can be subjected to a dry etch with a slope. As an example, the slope can be about 60 degrees.

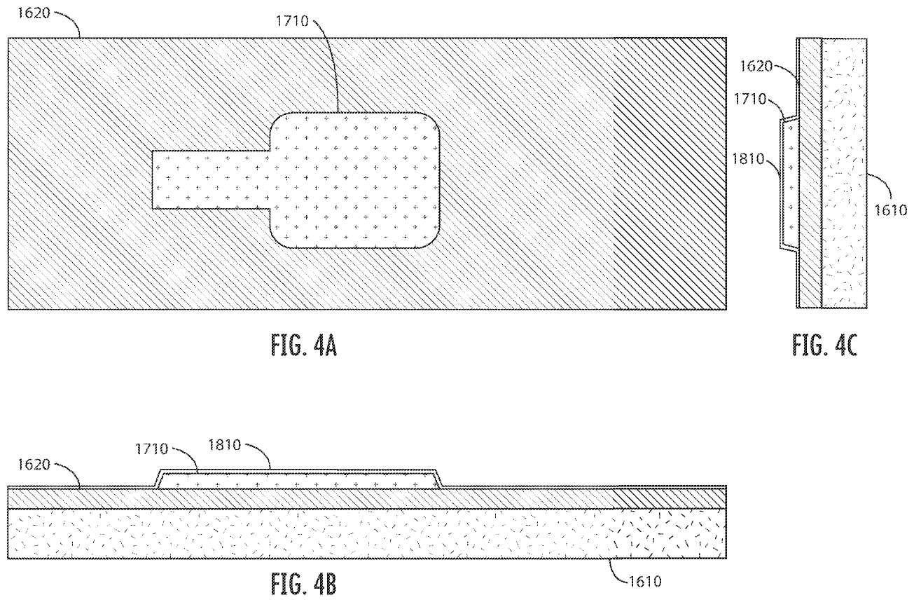

FIGS. 4A-4C are diagrams illustrating various cross-sectional views of a crystalline acoustic resonator device and of method steps for the transfer process using a sacrificial layer for crystalline acoustic resonator devices according to an example of the present inventive concept. As shown, these figures illustrate methods of forming a first passivation layer 1810 overlying the first electrode 1710 and the piezoelectric film 1620. In an example, the first passivation layer 1810 can include silicon nitride (SiN), silicon oxide (SiOx), or other like materials. In a specific example, the first passivation layer 1810 can have a thickness ranging from about 50 nm to about 100 nm. Other thicknesses can be used.

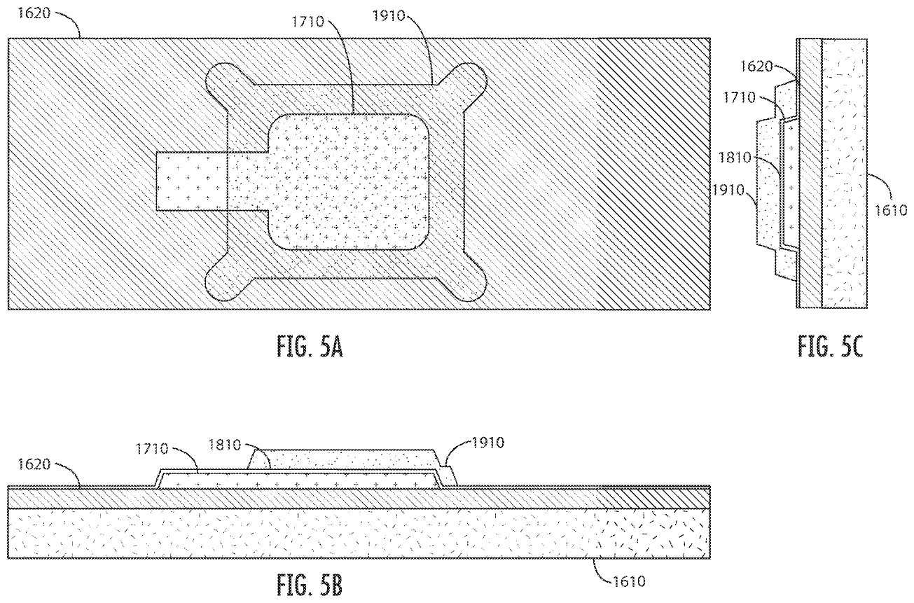

FIGS. 5A-5C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of forming a sacrificial layer 1910 overlying a portion of the first electrode 1810 and a portion of the piezoelectric film 1620. In an example, the sacrificial layer 1910 can include polycrystalline silicon (poly-Si), amorphous silicon (a-Si), or other like materials. In a specific example, this sacrificial layer 1910 can be subjected to a dry etch with a slope and be deposited with a thickness of about 1 um. Further, phosphorous doped SiO2 (PSG) can be used as the sacrificial layer with different combinations of support layer (e.g., SiNx).

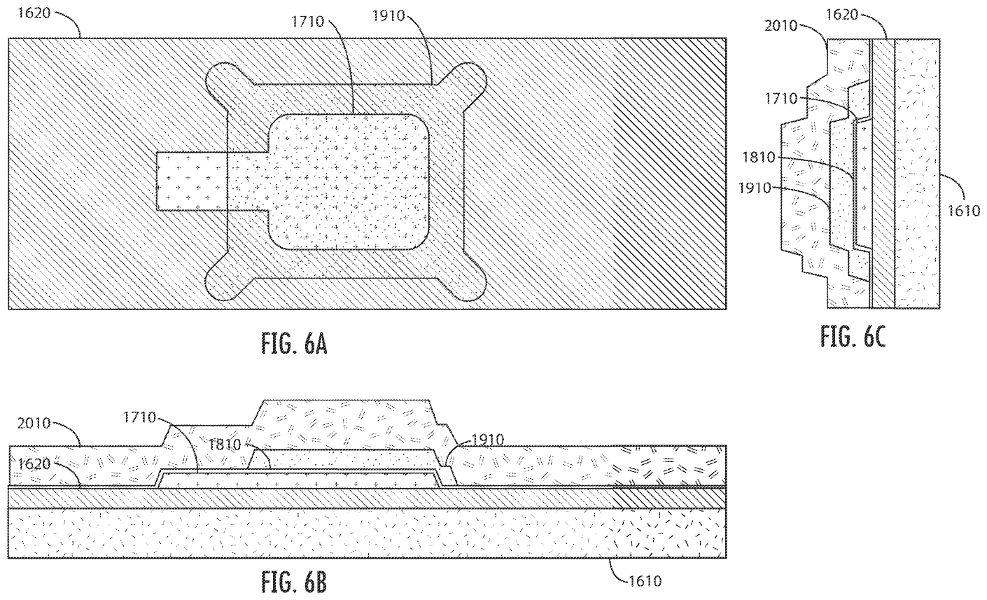

FIGS. 6A-6C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of forming a support layer 2010 overlying the sacrificial layer 1910, the first electrode 1710, and the piezoelectric film 1620. In an example, the support layer 2010 can include silicon dioxide (SiO2), silicon nitride (SiN), or other like materials. In a specific example, this support layer 2010 can be deposited with a thickness of about 2-3 um other thicknesses may be used. As described above, other support layers (e.g., SiNx) can be used in the case of a PSG sacrificial layer.

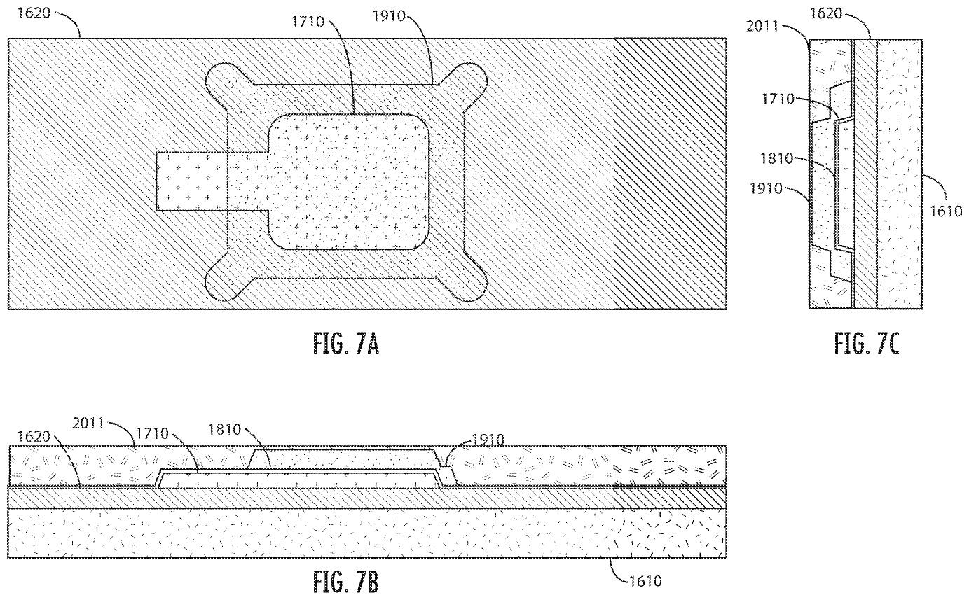

FIGS. 7A-7C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of polishing the support layer 2010 to form a polished support layer 2011. In an example, the polishing process can include a chemical-mechanical planarization process or the like.

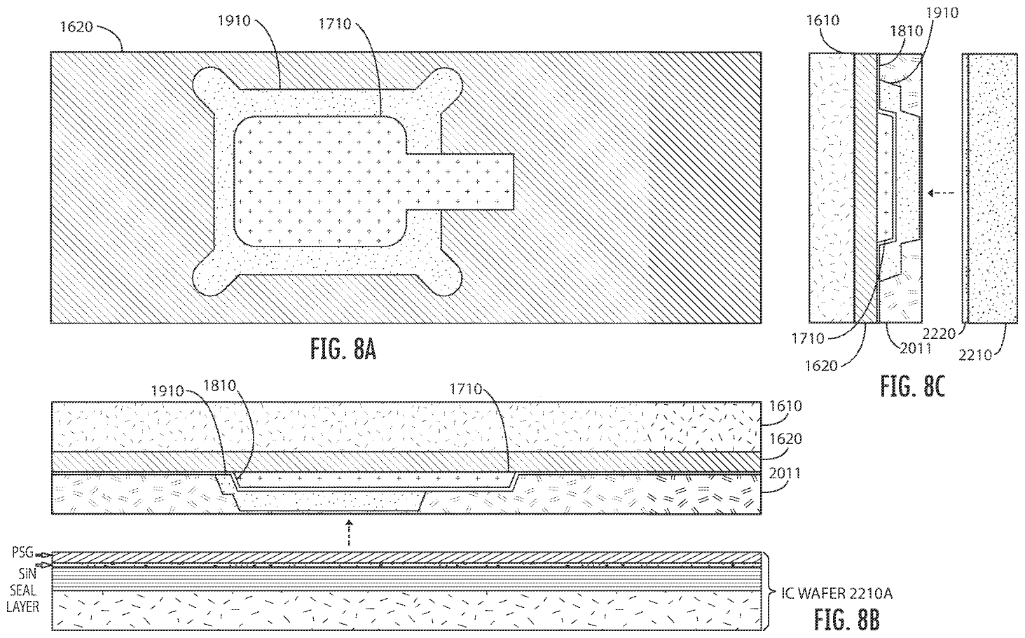

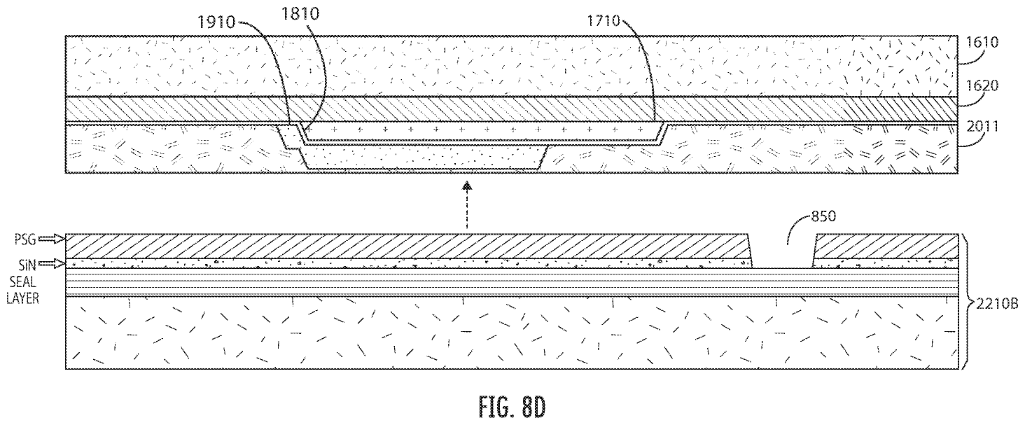

FIGS. 8A-8C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate coupling the overlying the support layer 2011 with an integrated circuit wafer 2210A that includes the electronic semiconductor switching devices which can be coupled to selected ones of the electrodes of the acoustic resonator devices in some embodiments. In an example, the integrated circuit wafer 2210A can include bonding support layer 2220 (SiO2 or like material) overlying the layers of the wafer that make up the BEOL portion of the wafer and the electronic semiconductor switching devices on a substrate, such as silicon (Si), sapphire (Al2O3), silicon dioxide (SiO2), silicon carbide (SiC), or other like materials.

In a specific embodiment, the bonding support layer 2220 of the integrated circuit wafer 2210 is physically coupled to the polished support layer 2011. Further, the physical coupling process can include a room temperature bonding process following by a 300 degree Celsius annealing process.

FIG. 8D is a diagram illustrating a cross-sectional view of a crystalline acoustic resonator device and of method steps for a transfer process using a sacrificial layer for crystalline acoustic resonator devices according to an example of the present inventive concept. As shown, FIG. 8B illustrates coupling the overlying the support layer 2011 with the integrated circuit wafer 2210B that includes the same structures as those shown in FIGS. 1A and 8A-8C and an opening that exposes at least one of the layers included in the BEOL layers of the wafer 2210B. Subsequently, when a corresponding opening 850 is formed in the acoustic device wafer that is aligned to the opening 850 in the wafer 2210B, a conductive layer can be formed in the opening 850 to ohmically couple an electrode of the acoustic resonator device to at least one of the electronic semiconductor switching devices of the IC wafer 2210B. In an example, the integrated circuit wafer 2210B can include the bonding support layer 2220 (SiO2 or like material) overlying the layers of the wafer that make up the BEOL portion of the wafer and the electronic semiconductor switching devices on a substrate. In some embodiments according to the inventive concept, the substrate can be silicon (Si), sapphire (Al2O3), silicon dioxide (SiO2), silicon carbide (SiC), or other like materials.

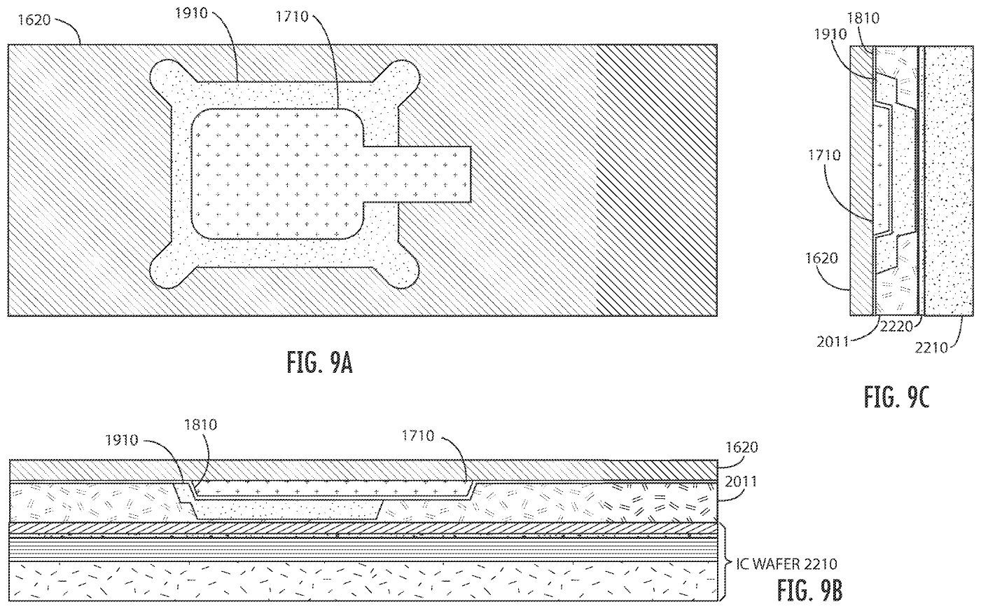

FIGS. 9A-9C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of removing the growth substrate 1610 to expose the surface the piezoelectric film 1620 that was covered by the growth substrate as illustrated in FIGS. 2-8. In an example, the removal process can include a grinding process, a blanket etching process, a film transfer process, an ion implantation transfer process, a laser crack transfer process, or the like and combinations thereof.

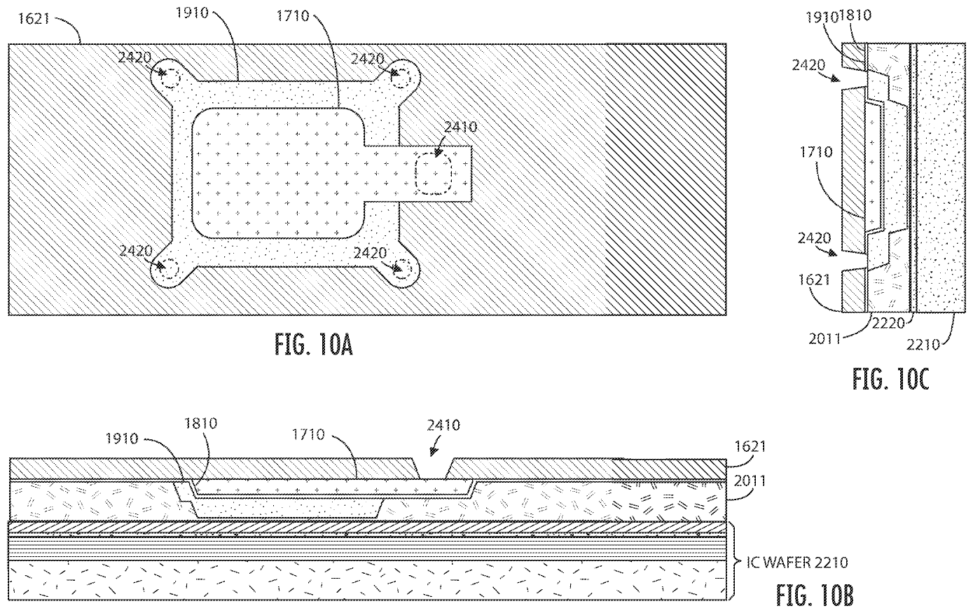

FIGS. 10A-10C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of forming an electrode contact via 2410 within the piezoelectric film 1621 (becoming piezoelectric film 1621) overlying the first electrode 1710 and forming one or more release holes 2420 within the piezoelectric film 1621 and the first passivation layer 1810 overlying the sacrificial layer 1910. The via forming processes can include various types of etching processes.

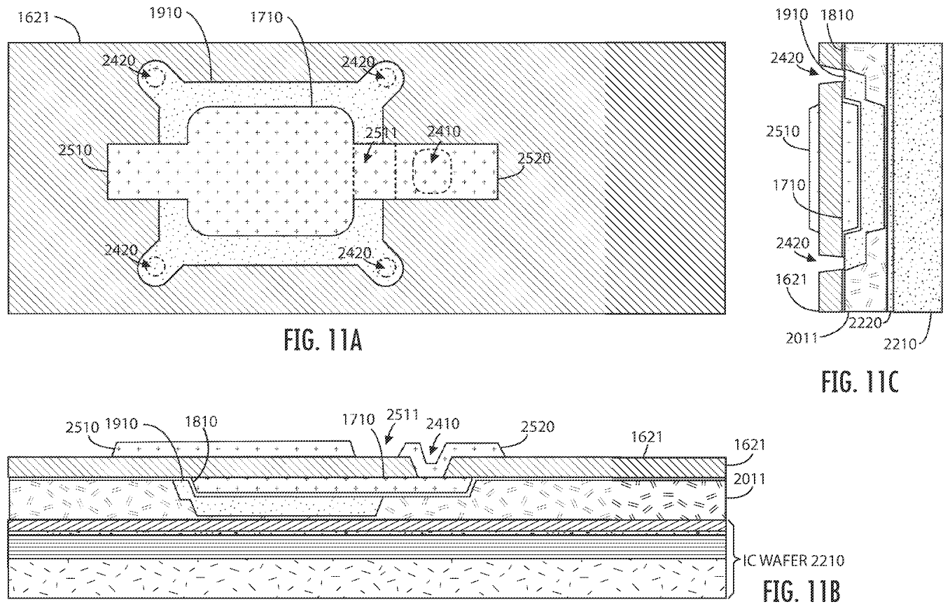

FIGS. 11A-11C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of forming a second electrode 2510 overlying the piezoelectric film 1621. In an example, the formation of the second electrode 2510 includes depositing molybdenum (Mo), ruthenium (Ru), tungsten (W), or other like materials; and then etching the second electrode 2510 to form an electrode cavity 2511 in the second electrode to form a top metal 2520. Further, the top metal 2520 is ohmically coupled to the first electrode 1710 through electrode contact via 2410.

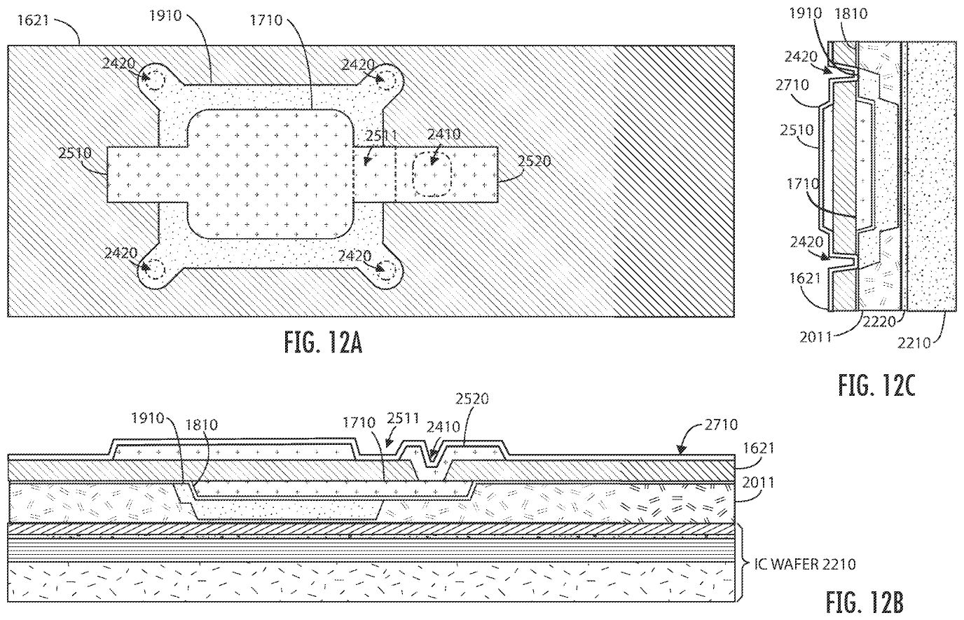

FIGS. 12A-12C are diagrams illustrating various cross-sectional views of a crystalline acoustic resonator device and of method steps for a transfer process using a sacrificial layer for crystalline acoustic resonator devices according to an example of the present inventive concept. According to FIGS. 12A-12C, a passivation layer 2710 is formed on the surface of the piezoelectric film 1621, the top metal 2520 and the second electrode 2510. In an example, the second passivation layer 2710 can include silicon nitride (SiN), silicon oxide (SiOx), or other like materials. In a specific example, the second passivation layer 2710 can have a thickness ranging from about 50 nm to about 100 nm. Other thicknesses can be used.

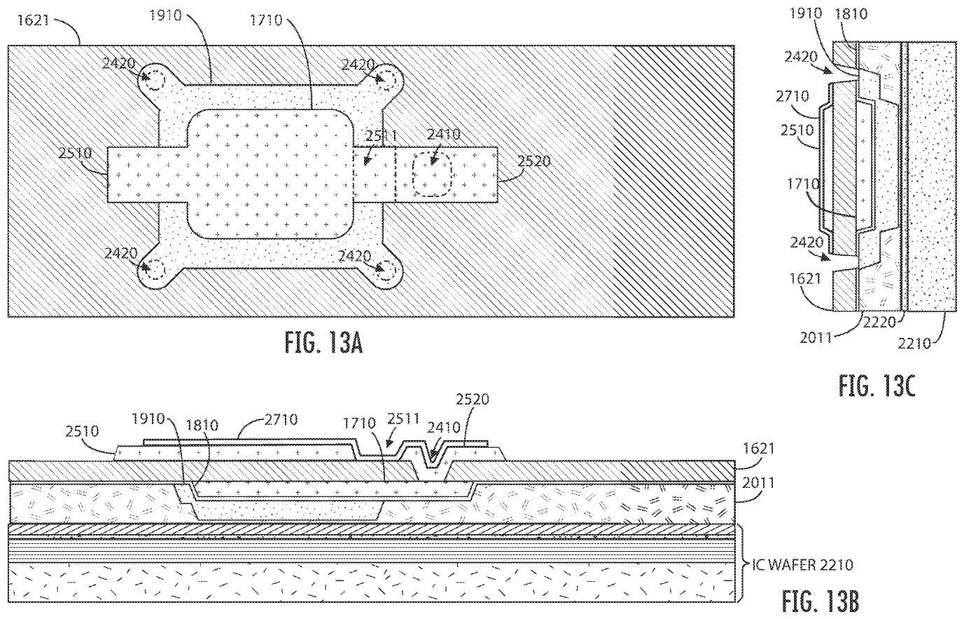

FIGS. 13A-13C are diagrams illustrating various cross-sectional views of a crystalline acoustic resonator device and of method steps for a transfer process using a sacrificial layer for crystalline acoustic resonator devices according to an example of the present inventive concept. According to FIGS. 13A-13C, the passivation layer 2710 is patterned and etched to expose the outer edge of the top metal 2520, the outer edge of the second electrode 2510, and the surface of the piezoelectric film 1621.

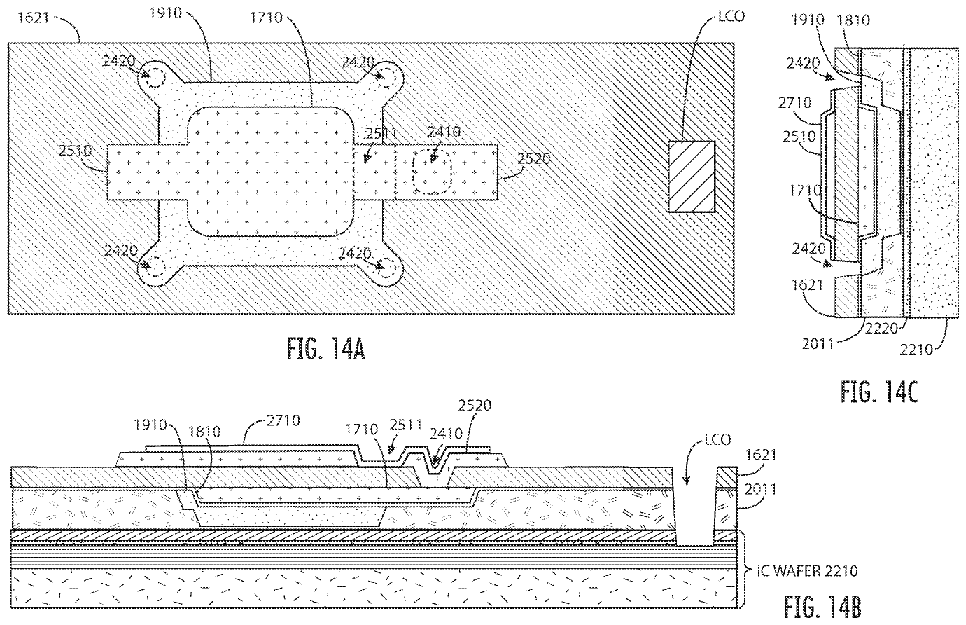

FIGS. 14A-14C are diagrams illustrating various cross-sectional views of a crystalline acoustic resonator device and of method steps for a transfer process using a sacrificial layer for crystalline acoustic resonator devices according to an example of the present inventive concept. According to FIGS. 14A-14C, an opening LCO is formed to expose an upper surface of the integrated circuit wafer 2210 including at least one of the ohmic conductors that couple the electronic semiconductor switching devices to the outer ones of the second layers included in the BEOL portion of the wafer 2210.

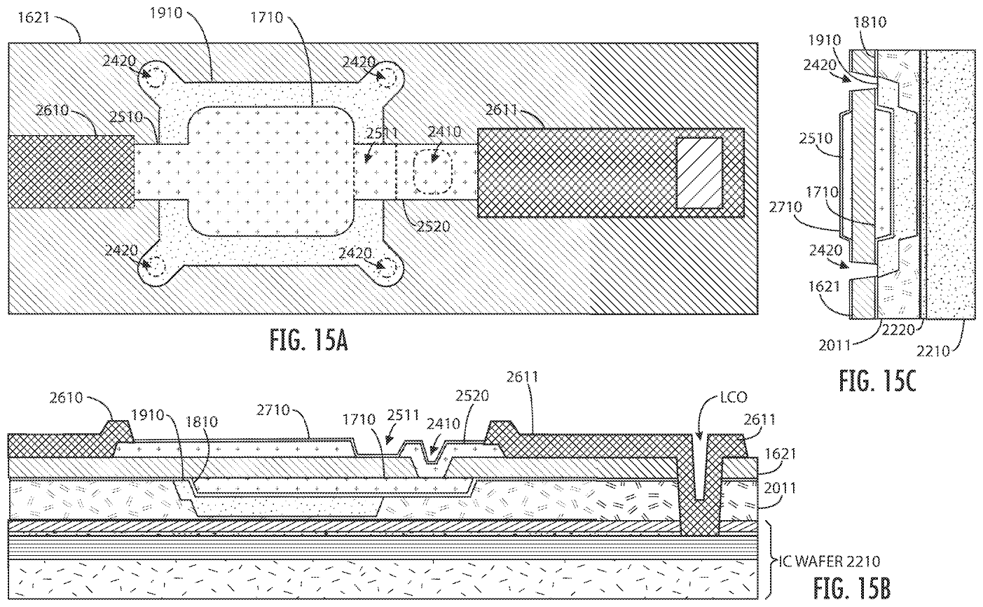

FIGS. 15A-15C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of forming a conductive layer on the acoustic resonator device to form a first contact metal 2610 overlying a portion of the second electrode 2510 and a portion of the piezoelectric film 1621, and forming a second contact metal 2611 overlying a portion of the top metal 2520 and a portion of the piezoelectric film 1621. Further, the conductive layer extends on the piezoelectric film 1621 into the opening LCO to contact the exposed upper surface of the integrated circuit wafer 2210 including the at least one of the ohmic conductors that couple the electronic semiconductor switching devices to the outer ones of the second layers included in the BEOL portion of the wafer 2210. In an example, the first and second contact metals can include gold (Au), aluminum (Al), copper (Cu), nickel (Ni), aluminum bronze (AlCu), or related alloys of these materials or other like materials.

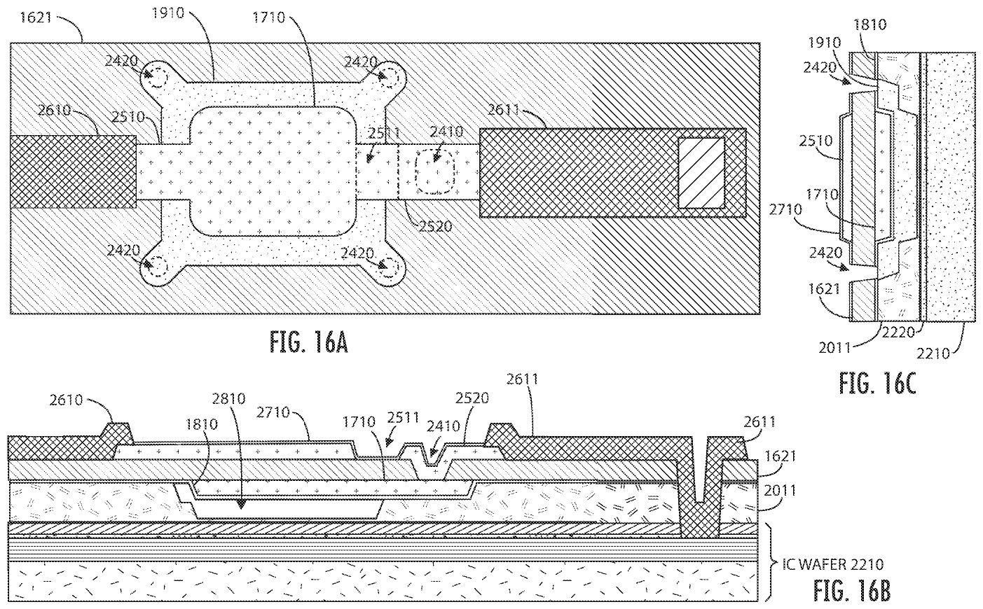

FIGS. 16A-16C are diagrams illustrating various cross-sectional views of a crystalline acoustic resonator device and of method steps for a transfer process using a sacrificial layer for crystalline acoustic resonator devices according to an example of the present inventive concept. As shown, these figures illustrate methods of removing the sacrificial layer 1910 to form an air cavity 2810. In an example, the removal process can include a poly-Si etch or an a-Si etch, or the like.

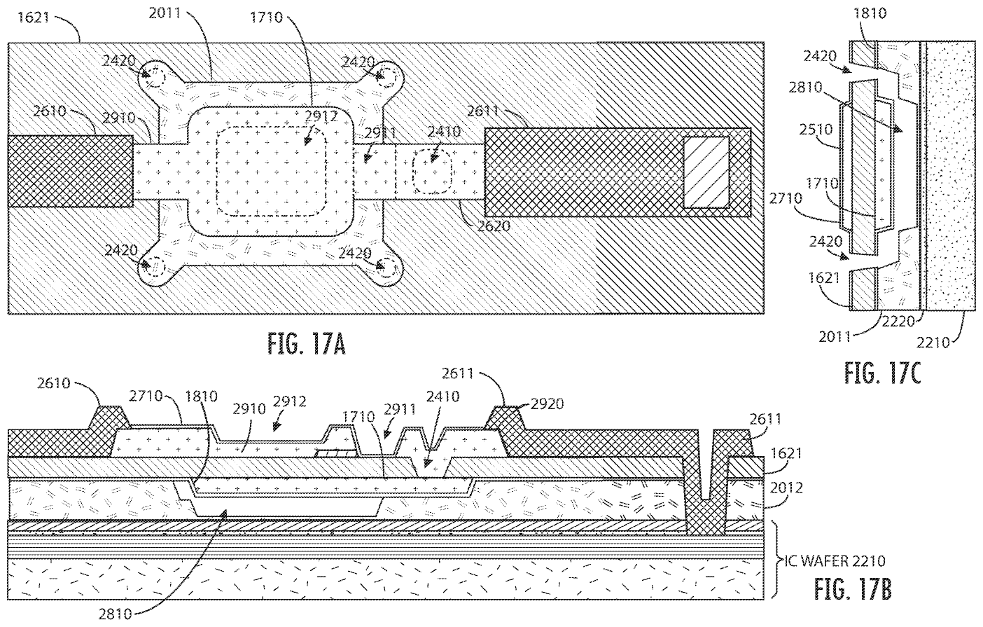

FIGS. 17A-17C are diagrams illustrating various cross-sectional views of a crystalline acoustic resonator device and of method steps for a transfer process using a sacrificial layer for crystalline acoustic resonator devices according to another example of the present inventive concept. As shown, these figures illustrate methods of processing the second electrode 2510 and the top metal 2520 to form a processed second electrode 2910 and a processed top metal 2920. This step can follow the formation of second electrode 2510 and top metal 2520. In an example, the processing of these two components includes depositing molybdenum (Mo), ruthenium (Ru), tungsten (W), or other like materials; and then etching (e.g., dry etch or the like) this material to form the processed second electrode 2910 with an electrode cavity 2912 and the processed top metal 2920. The processed top metal 2920 remains separated from the processed second electrode 2910 by the removal of portion 2911. In a specific example, the processed second electrode 2910 is characterized by the addition of an energy confinement structure configured on the processed second electrode 2910 to increase Q.

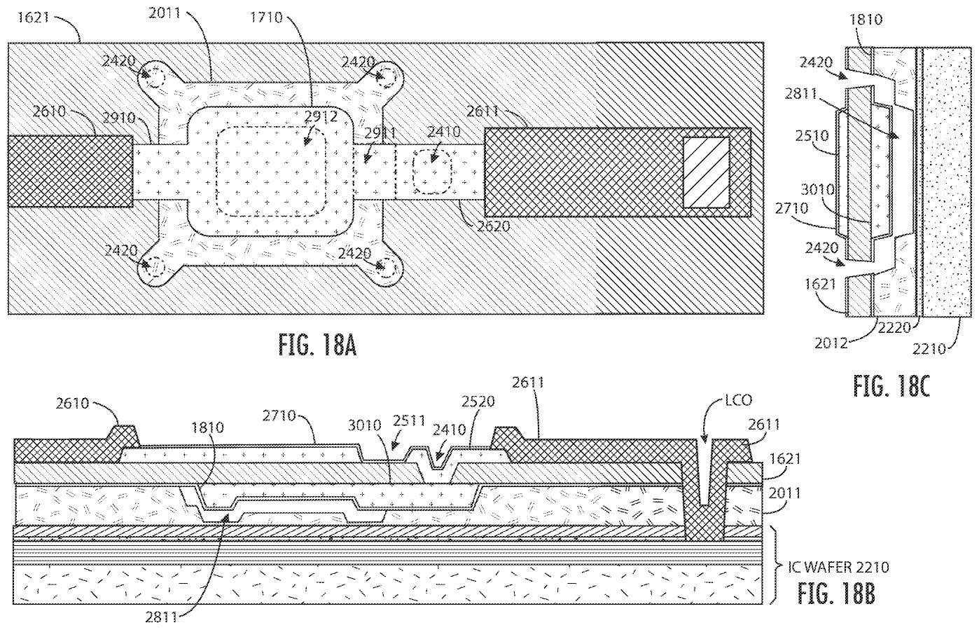

FIGS. 18A-18C are diagrams illustrating various cross-sectional views of a crystalline acoustic resonator device and of method steps for a transfer process using a sacrificial layer for crystalline acoustic resonator devices according to another example of the present inventive concept. As shown, these figures illustrate methods of processing the first electrode 1710 to form a processed first electrode 3010. This step can follow the formation of first electrode 1710. In an example, the processing of these two components includes depositing molybdenum (Mo), ruthenium (Ru), tungsten (W), or other like materials; and then etching (e.g., dry etch or the like) this material to form the processed first electrode 3010 with an electrode cavity, similar to the processed second electrode 2910. Air cavity 2811 shows the change in cavity shape due to the processed first electrode 3010. In a specific example, the processed first electrode 3010 is characterized by the addition of an energy confinement structure configured on the processed second electrode 3010 to increase Q.

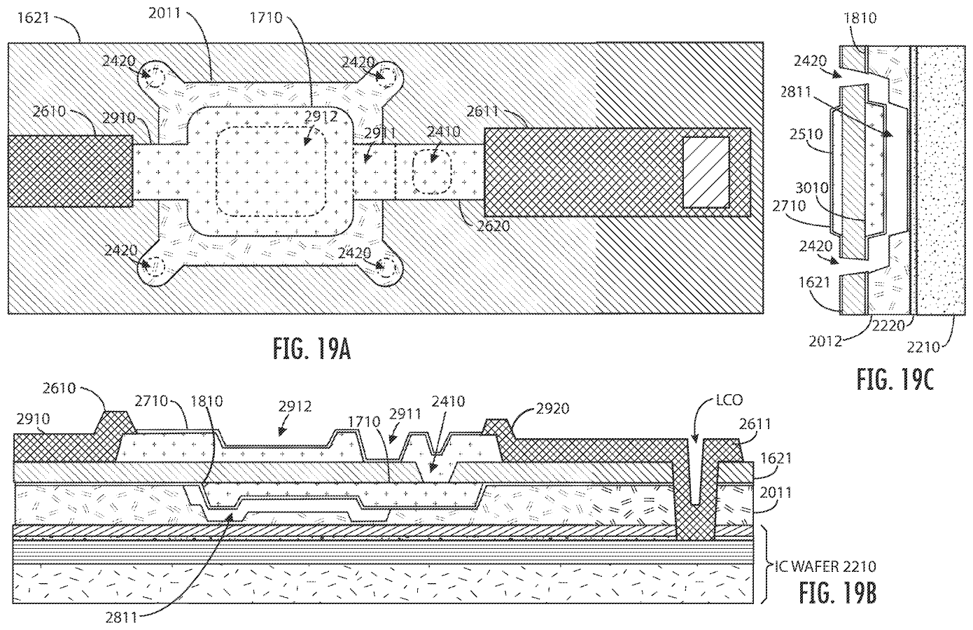

FIGS. 19A-19C are diagrams illustrating various cross-sectional views of a crystalline acoustic resonator device and of method steps for a transfer process using a sacrificial layer for crystalline acoustic resonator devices according to another example of the present inventive concept. As shown, these figures illustrate methods of processing the first electrode 1710, to form a processed first electrode 3010, and the second electrode 2510/top metal 2520 to form a processed second electrode 2910/processed top metal 2920. These steps can follow the formation of each respective electrode, as described for FIGS. 17A-17C and 18A-18C. Those of ordinary skill in the art will recognize other variations, modifications, and alternatives.

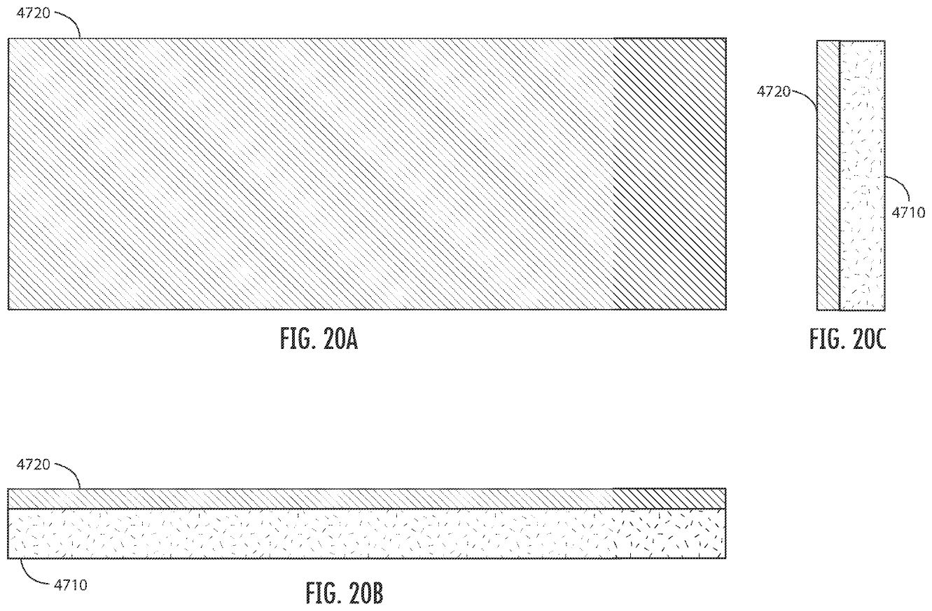

FIGS. 20A-20C through FIGS. 35A-35C illustrate methods of bonding acoustic resonator device wafers (having a multilayer mirror structure) to integrated circuit wafers where the respective devices therein can be coupled together as part of the transfer process described herein to provide wafers that include integrated devices using a sacrificial layer. In these figure series described below, the “A” figures show diagrams illustrating top cross-sectional views of crystalline resonator devices included in an acoustic device wafer transferred to corresponding electronic semiconductor switch devices included in an integrated circuit wafer according to various embodiments of the present invention. The “B” figures show diagrams illustrating lengthwise cross-sectional views of the same devices in the “A” figures. Similarly, the “C” figures show diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

Accordingly, it will be understood that the devices shown are representative of a plurality of devices that are included in the wafer which can also be subjected to the transfer processes described herein. Further it will be understood that when a reference is made to, for example, a crystalline acoustic resonator device, that device represents a portion of the wafer being processed. Still further, the “transfer process” refers to the formation of a portion of the acoustic resonator devices in the wafer followed by bonding those portions to the integrated circuit wafer followed by the completion of the acoustic resonator devices and the integration of the acoustic resonator devices with the electronic semiconductor switching devices in some embodiments.

According to FIGS. 20A-20C a piezoelectric film 4720 is formed on a growth substrate 4710. In an example, the growth substrate 4710 can include silicon (S), silicon carbide (SiC), or other like materials. The piezoelectric film 4720 can be an epitaxial or sputtered film including aluminum nitride (AlN), gallium nitride (GaN), or other like materials. Additionally, this piezoelectric film can be subjected to a thickness trim.

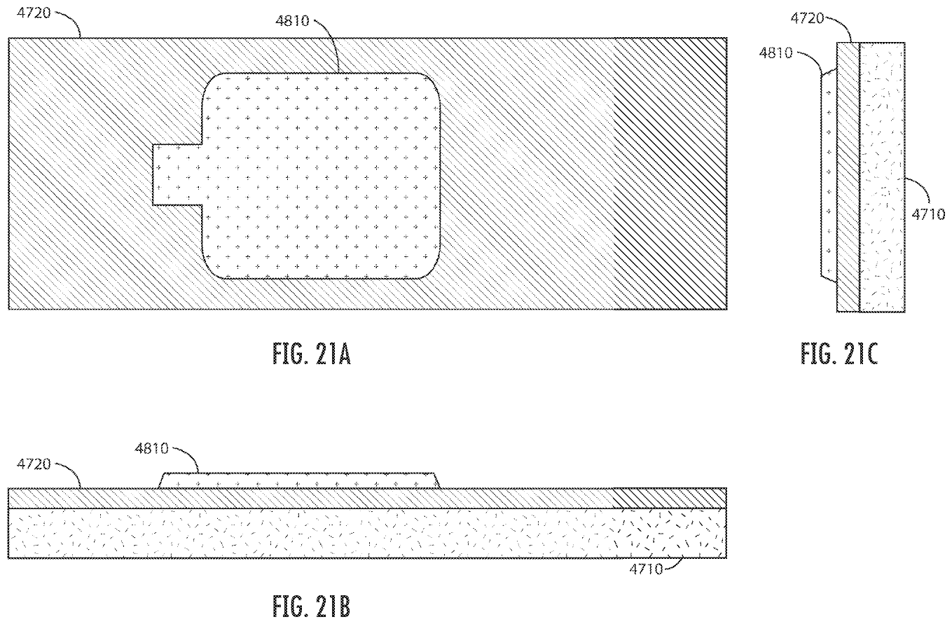

According to FIGS. 21A-21C a first electrode 4810 is formed on the surface region of the piezoelectric film 4720. In an example, the first electrode 4810 can include molybdenum (Mo), ruthenium (Ru), tungsten (W), or other like materials. In a specific example, the first electrode 4810 can be subjected to a dry etch with a slope. As an example, the slope can be about 60 degrees.

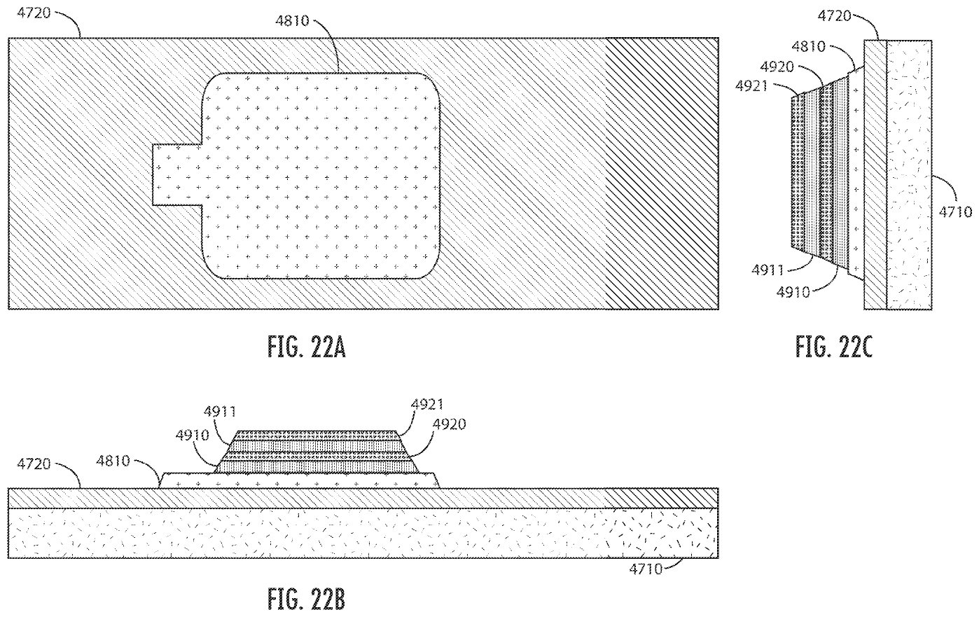

According to FIGS. 22A-22C a multilayer mirror or reflector structure is formed on the first electrode 4810. In an example, the multilayer mirror includes at least one pair of layers with a low impedance layer 4910 and a high impedance layer 4920. In FIGS. 22A-22C, two pairs of low/high impedance layers are shown (low: 4910 and 4911; high: 4920 and 4921). In an example, the mirror/reflector area can be larger than the resonator area and can encompass the resonator area. In a specific embodiment, each layer thickness is about ¼ of the wavelength of an acoustic wave at a targeting frequency. The layers can be deposited in sequence and be etched afterwards, or each layer can be deposited and etched individually. In another example, the first electrode 4810 can be patterned before or after the mirror structure is patterned.

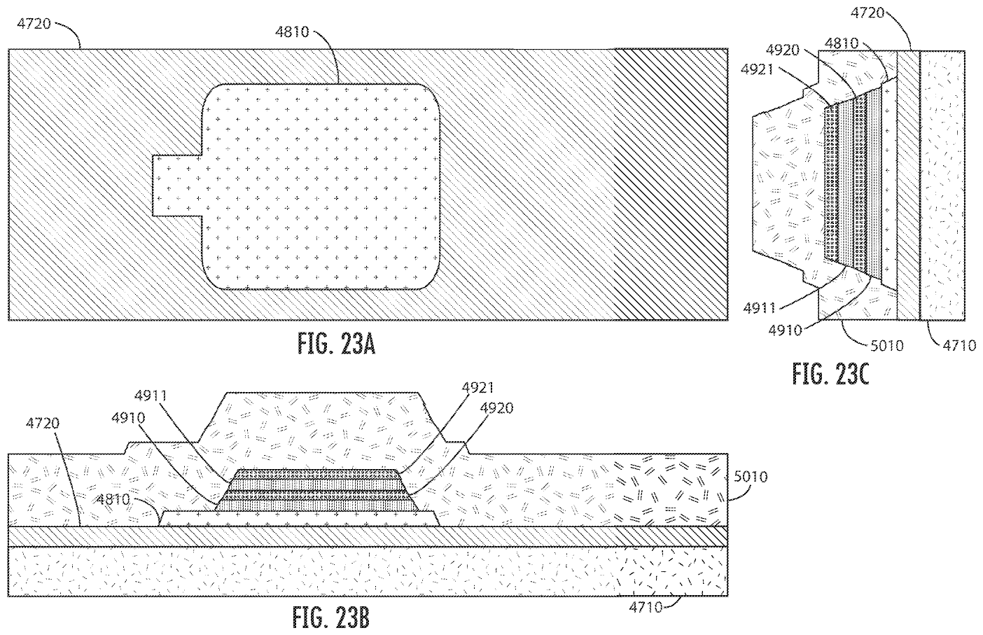

According to FIGS. 23A-23C a support layer 5010 is formed overlying the mirror structure (layers 4910, 4911, 4920, and 4921), the first electrode 4810, and the piezoelectric film 4720. In an example, the support layer 5010 can include silicon dioxide (SiO2), silicon nitride (SiN), or other like materials. In a specific example, this support layer 5010 can be deposited with a thickness of about 2-3 um. As described above, other support layers (e.g., SiNx) can be used. Other thicknesses can be used.

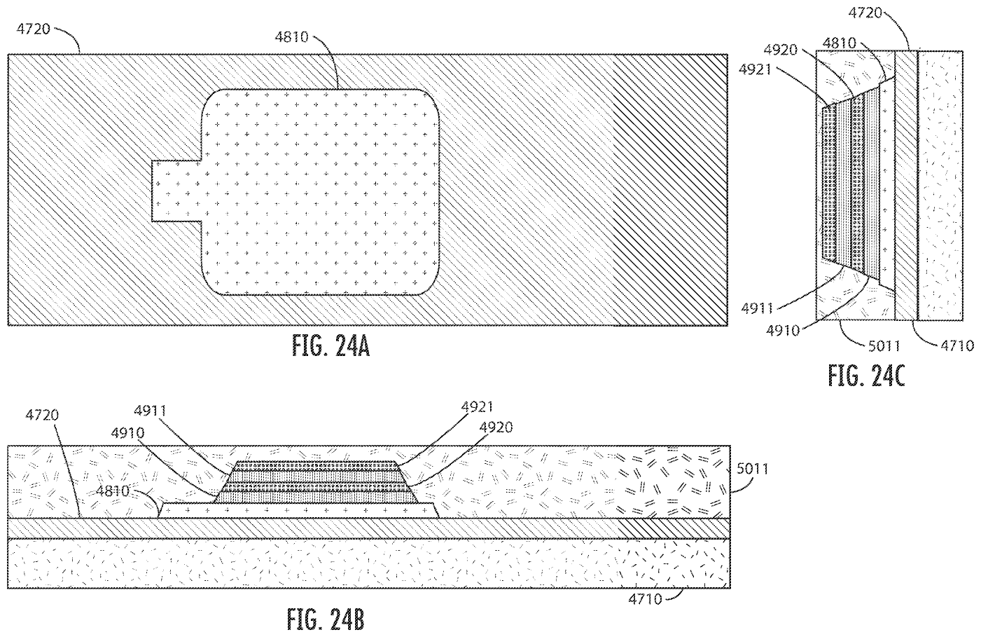

According to FIGS. 24A-24C the support layer 5010 is polished to form a polished support layer 5011. In an example, the polishing process can include a chemical-mechanical planarization process or the like.

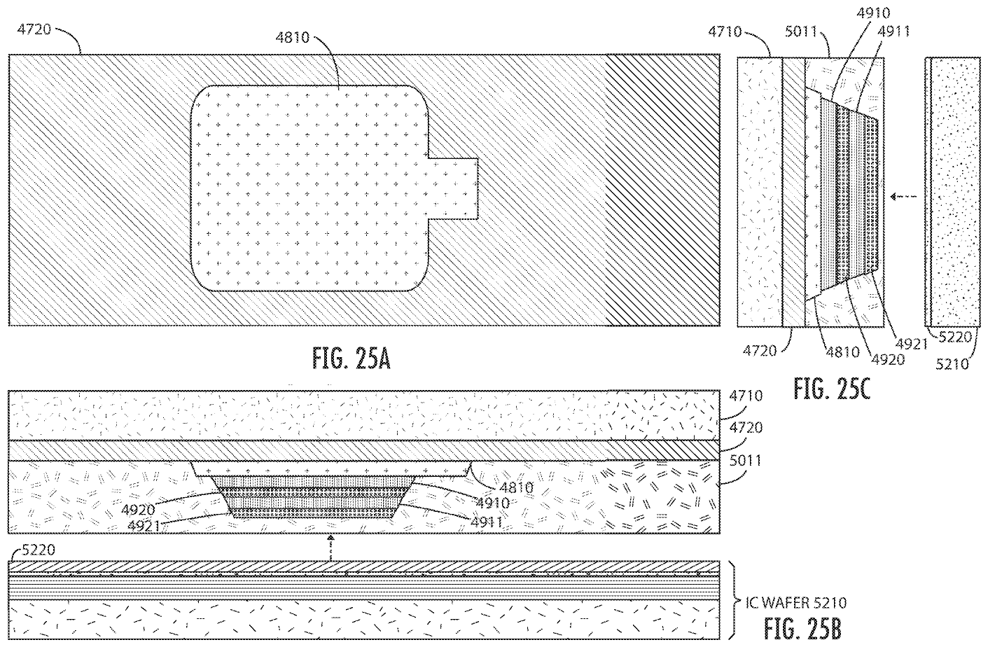

According to FIGS. 25A-25C the acoustic resonator wafer including the structure having the polished support layer 5011 is bonded to an integrated circuit wafer 5210 that includes the electronic semiconductor switching devices which can be coupled to selected ones of the electrodes of the acoustic resonator devices in some embodiments as shown, for example in FIG. 1A. In an example, the integrated circuit wafer 5210 can include a bonding support layer 5220 (SiO2 or like material). The integrated circuit wafer 5210 can be on a substrate including silicon (Si), sapphire (Al2O3), silicon dioxide (SiO2), silicon carbide (SiC), or other like materials. In a specific embodiment, the bonding support layer 5220 of the integrated circuit wafer 5210 is coupled to the polished support layer 5011. Further, the coupling process can include a room temperature bonding process following by a 300 degree Celsius annealing process. In some embodiments, the integrated circuit wafer 5210 can be the integrated circuit wafer of FIG. 8D.

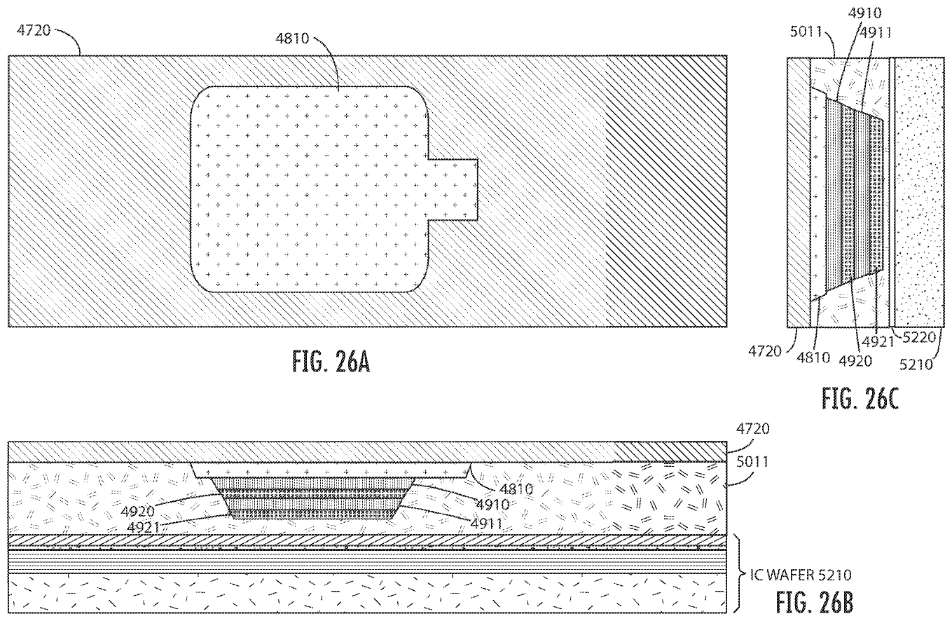

According to FIGS. 26A-26C the growth substrate 4710 is removed so that the piezoelectric film 4720 can be further processed from the reverse side using integrated circuit wafer 5210 to support the acoustic resonator wafer. In an example, the removal process can include a grinding process, a blanket etching process, a film transfer process, an ion implantation transfer process, a laser crack transfer process, or the like and combinations thereof.

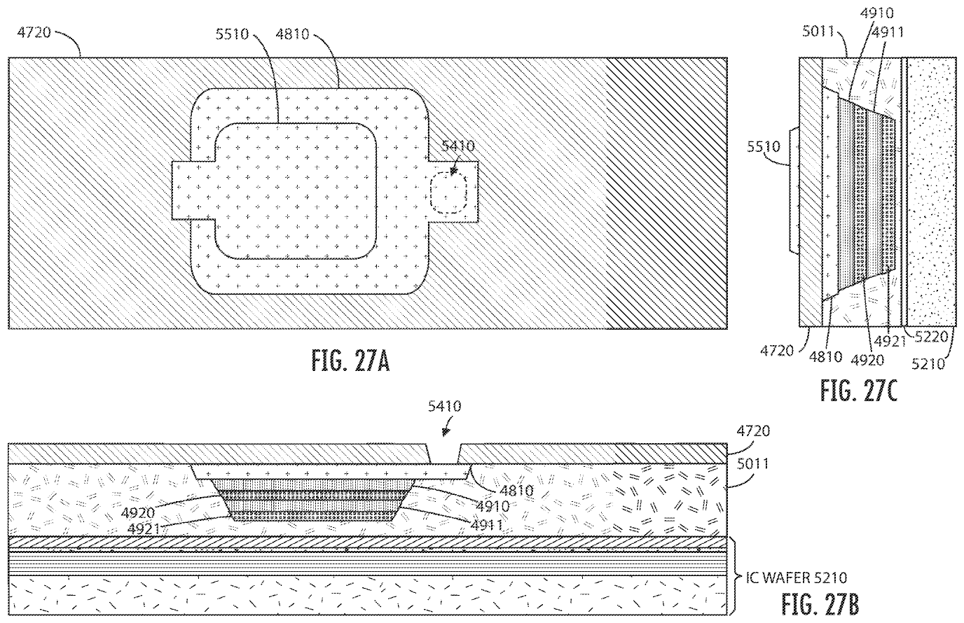

According to FIGS. 27A-27C an electrode contact via 5410 is formed within the piezoelectric film 4720 to expose the first electrode 4810. The via forming processes can include various types of etching processes.

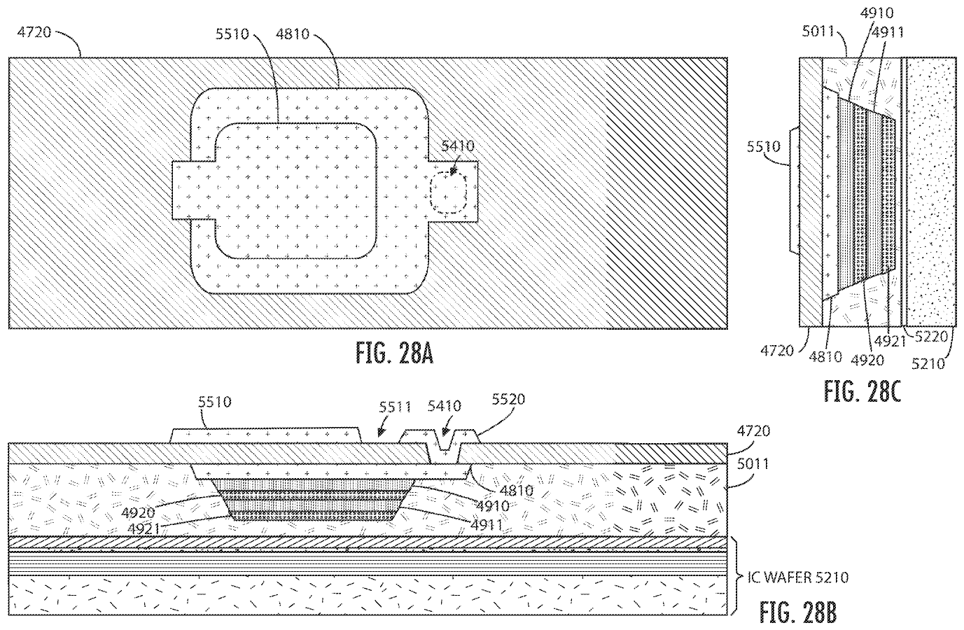

According to FIGS. 28A-28C a conductive layer is deposited and patterned to form a second electrode 5510 overlying the piezoelectric film 4720. In an example, the formation of the second electrode 5510 includes depositing molybdenum (Mo), ruthenium (Ru), tungsten (W), or other like materials; and then etching to form an electrode cavity 5511 in the second electrode to form a top metal 5520. Further, the top metal 5520 is ohmically coupled to the first electrode 5520 through electrode contact via 5410.

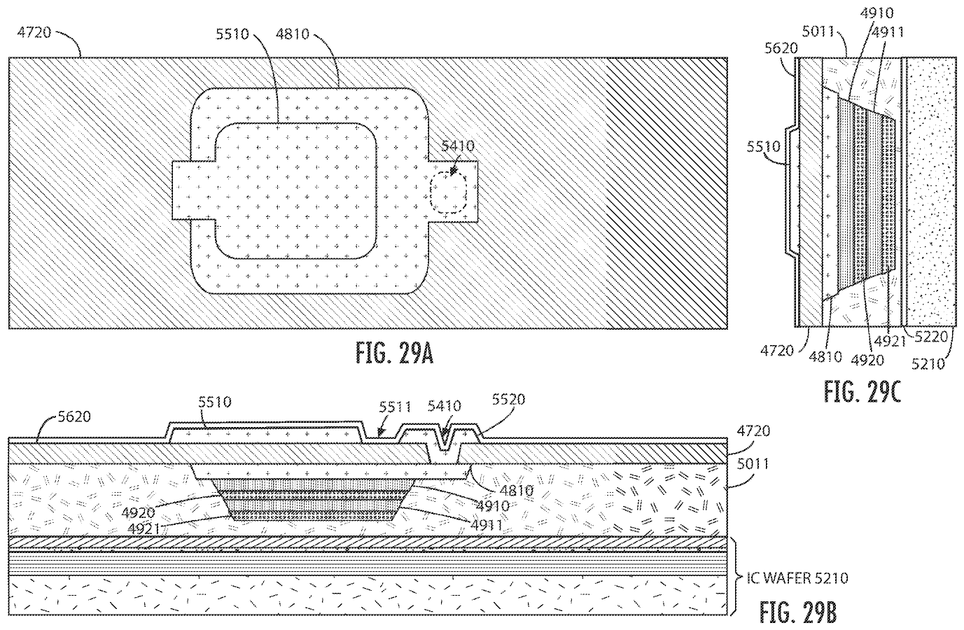

According to FIGS. 29A-29C a second passivation layer 5620 is formed on the second electrode 5510, the top metal 5520, and the piezoelectric film 4720. In an example, the second passivation layer 5620 can include silicon nitride (SiN), silicon oxide (SiOx), or other like materials. In a specific example, the second passivation layer 5620 can have a thickness ranging from about 50 nm to about 100 nm. Other thicknesses can be used.

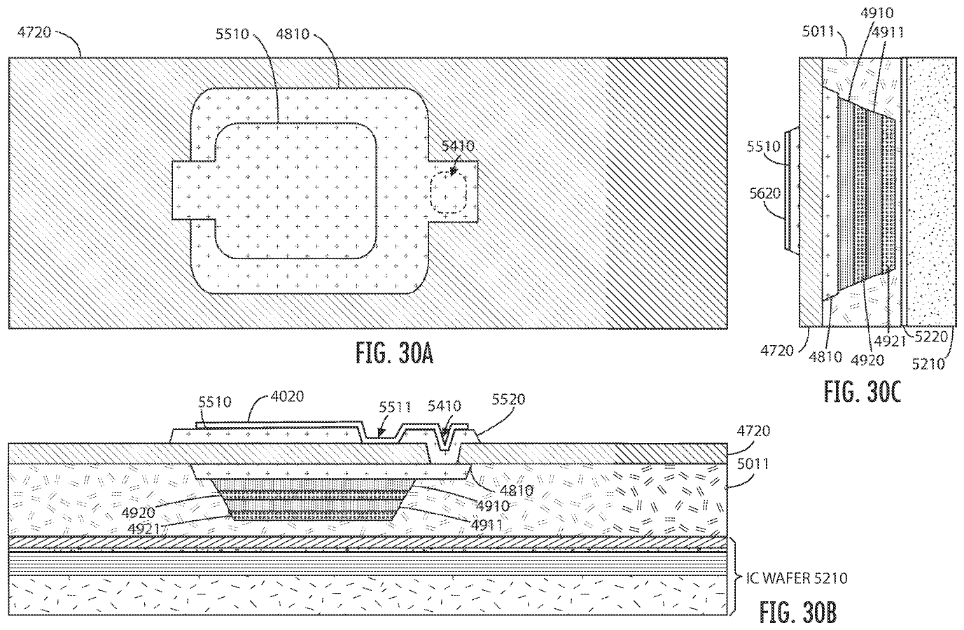

According to FIGS. 30A-30C, the second passivation layer 5620 is patterned and etched to expose the outer edges of the top metal 5520 and the second electrode 5510.

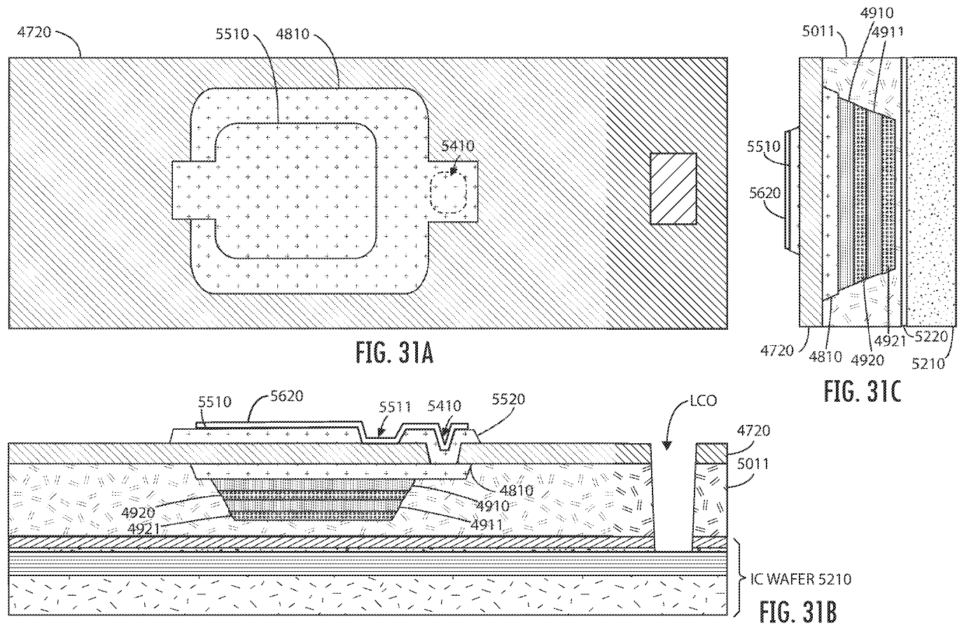

According to FIGS. 31A-31C, an opening LCO is formed to expose an upper surface of the integrated circuit wafer 5210 including at least one of the ohmic conductors that couple the electronic semiconductor switching devices to the outer ones of the second layers included in the BEOL portion of the wafer 5210.

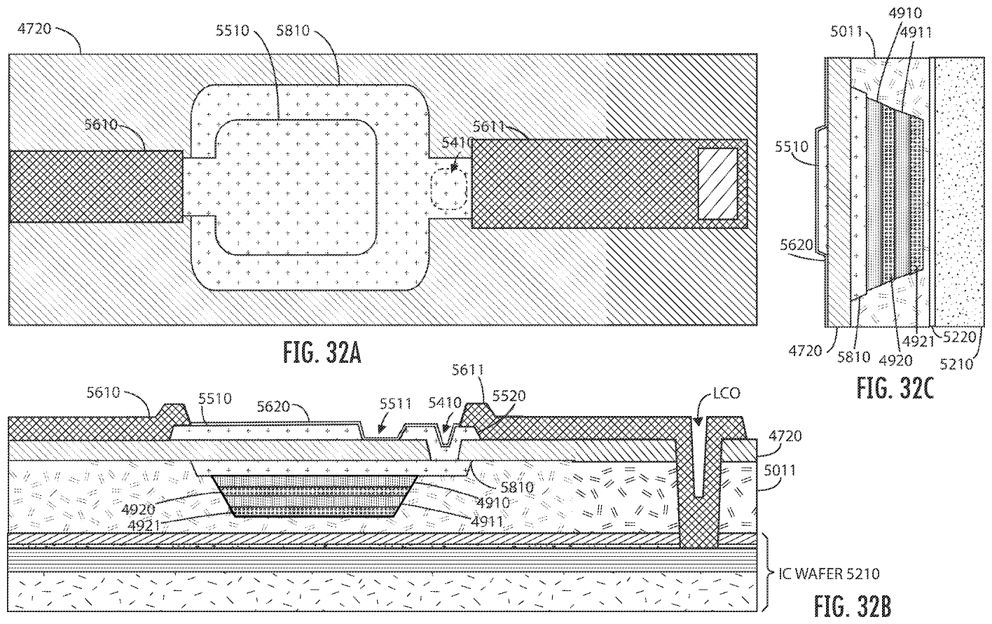

According to FIGS. 32A-32C, a first contact metal 5610 is formed on the outer portion of the second electrode 5510 and a second contact metal 5611 is formed on the outer portion of the top metal 5520 and onto a portion of the piezoelectric film 4720 an into the opening LCO to contact the at least one of the ohmic conductors that couple the electronic semiconductor switching devices to the outer ones of the second layers included in the BEOL portion of the wafer 5210. In an example, the first and second contact metals can include gold (Au), aluminum (Al), copper (Cu), nickel (Ni), aluminum bronze (AlCu), or other like materials.

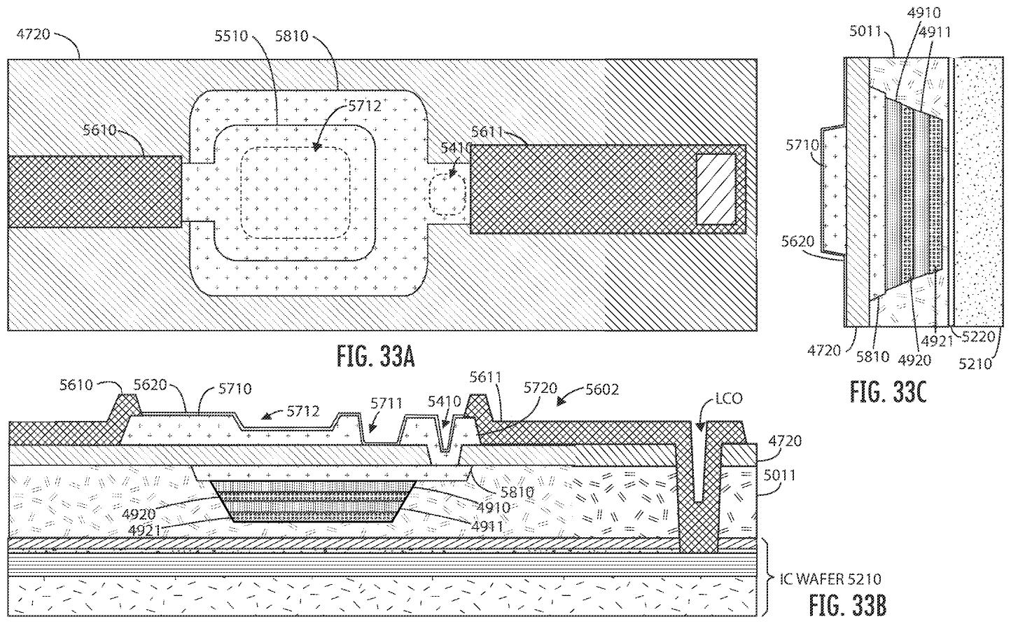

According to FIGS. 33A-33C the second electrode 5510 and the top metal 5520 are processed to form a processed second electrode 5710 and a processed top metal 5720. This step can follow the formation of second electrode 5710 and top metal 5720. In an example, the processing of these two components includes depositing molybdenum (Mo), ruthenium (Ru), tungsten (W), or other like materials; and then etching (e.g., dry etch or the like) this material to form the processed second electrode 5710 with an electrode cavity 5712 and the processed top metal 5720. The processed top metal 5720 remains separated from the processed second electrode 5710 by the removal of portion 5711. In a specific example, this processing gives the second electrode and the top metal greater thickness while creating the electrode cavity 5712. In a specific example, the processed second electrode 5710 is characterized by the addition of an energy confinement structure configured on the processed second electrode 5710 to increase Q.

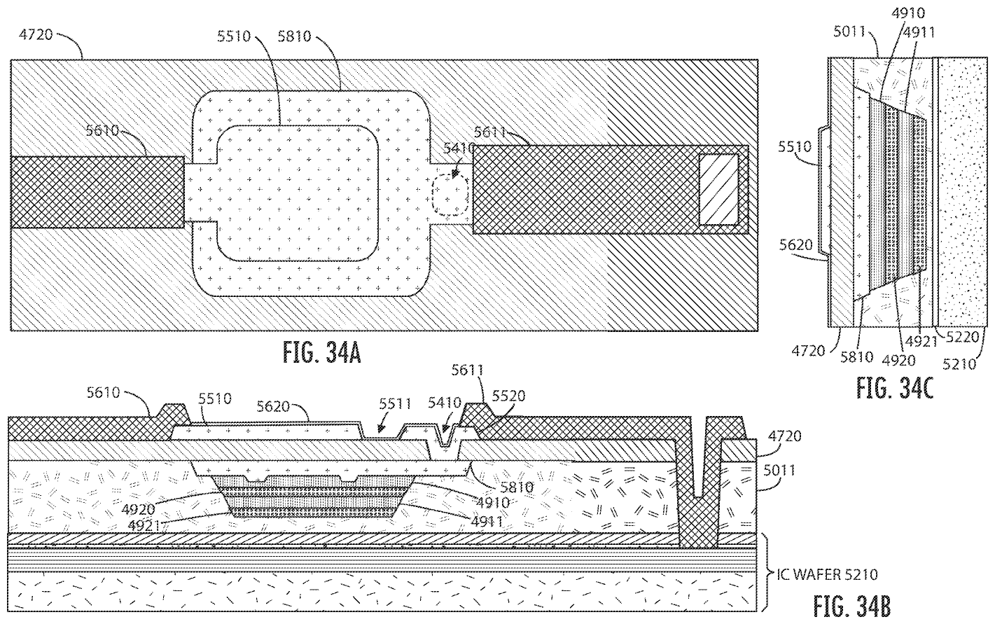

According to FIGS. 34A-34C, the first electrode 4810 is processed to form a processed first electrode 5810. This step can follow the formation of first electrode 4810 (see FIGS. 21A-21C). In an example, the processing of these two components can include depositing molybdenum (Mo), ruthenium (Ru), tungsten (W), or other like materials; and then etching (e.g., dry etch or the like) this material to form the processed first electrode 5810 with an electrode cavity, similar to the processed second electrode 5710. In a specific example, the processed first electrode 5810 is characterized by the addition of an energy confinement structure configured on the processed second electrode 5810 to increase Q.

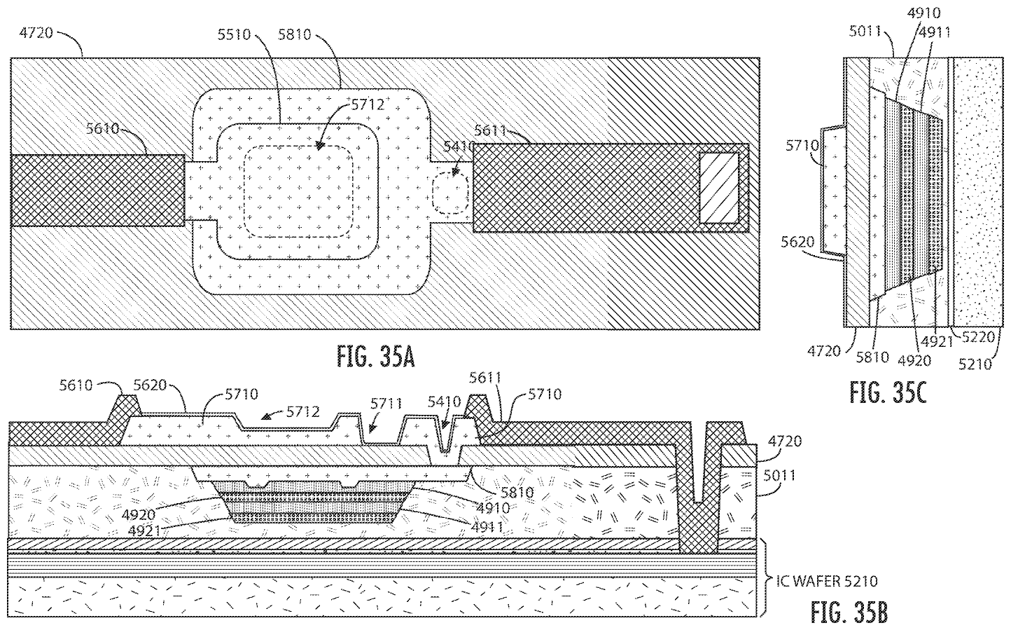

According to FIGS. 35A-35C the first electrode 4810 and the second electrode 5510/top metal 5520 are processed to form a processed first electrode 5810 and a processed second electrode 5710/processed top metal 5720, respectively. These steps can follow the formation of each respective electrode, as described for FIGS. 33A-33C and 34A-34C. Those of ordinary skill in the art will recognize other variations, modifications, and alternatives.

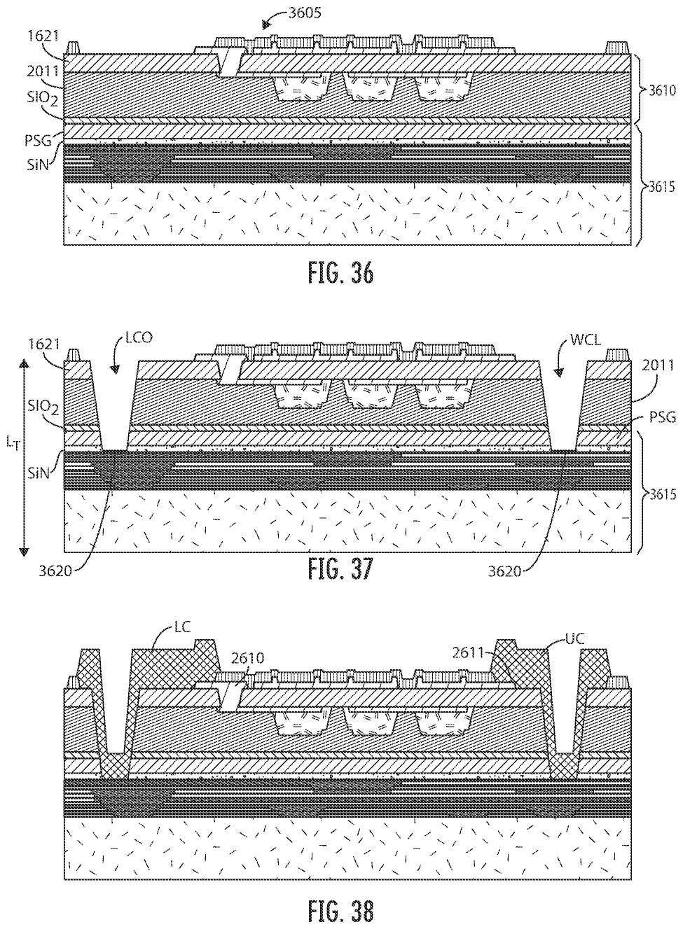

FIG. 36 is a cross-sectional diagram showing a plurality of acoustic resonator devices 3605 included in an acoustic resonator device wafer 3610 bonded to an integrated circuit wafer 3615 using the transfer process described herein in some embodiments. In particular, the integrated circuit wafer 3615 includes the SiN seal layer on the PSG layer to provide the surface for the bonding interface. The acoustic resonator device wafer 3610 can include a SiO2 layer that forms part of the bonding interface. The SiO2 layer may be formed on the support layer of the acoustic resonator device wafer 3610 prior to bonding with the integrated circuit wafer 3615.

According to FIG. 37, openings UCO and LCO are formed through the piezoelectric resonator layer 1621, the support layer 2011, the SiO2 layer, the PSG layer and the SiN seal layer to expose respective ones of the ohmic conductors 3620 that are included in the layers of the BEOL portion.

According to FIG. 38, a conductive material, such as a metal described herein, is deposited on the first and second contact metal 2610 and 2611 and into the LCO and UCO to form a lower contact LC and an upper contact UC, respectively. The lower contact LC and an upper contact UC are ohmically coupled to the exposed ohmic conductors 3620 so that the upper and lower electrodes of the acoustic resonator devices are coupled to the regions of the electronic semiconductor switching devices in the FEOL portion of the integrated circuit wafer. Subsequently, the sacrificial layers beneath the acoustic resonator devices can be removed.

According to FIG. 38, the UCO and LCO openings can a width W of about 20 microns and a length L of about 50 microns. In some embodiments, the piezoelectric resonator layer can be formed of AlScN with a concentration of Sc in range between about 4% and about 42%. Other piezoelectric materials may be used, such as AlN. In some embodiments, the piezoelectric resonator layer can have a thickness T in a range between about 4000 Angstroms and about 3000 Angstroms. In some embodiments, a combined thickness CT of the acoustic resonator device wafer and the integrated circuit wafer as shown in FIG. 38 can be in a range between about 675 microns and about 775 microns.

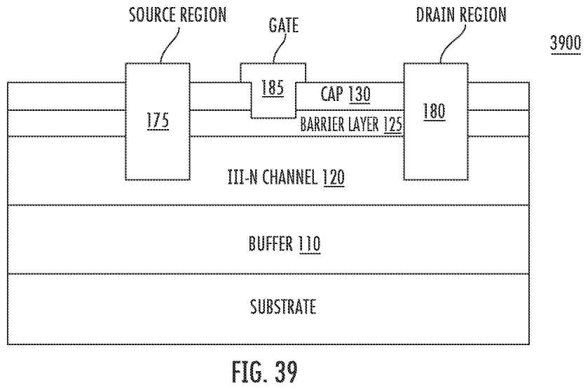

It will be understood that the integrated circuit wafer can include any technology electronic semiconductor switching devices. For example, FIG. 39 shows a cross-sectional diagram showing a GaN HEMT device 3900 that can be the electronic semiconductor switching device included in the FEOL portion of the integrated circuit wafer in some embodiments. In particular, the GaN HEMT device 3900 can include a HEMT stack of materials A that form the active layers of the HEMT device 3900, including a substrate having a barrier layer 110, a III-N channel layer 120, a barrier layer 125 and an optional cap layer 130 formed thereon. It will be understood that the ohmic conductors of the layers in the BEOL portion of the integrated circuit wafer can be used to couple the electrodes of the acoustic resonator devices to the source region 175, drain region 180, and the gate 185 of the GaN HEMT device 3900. Wafer with other types of electronic semiconductor switching devices can also be used.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

What is claimed:

1. A method of forming a BAW resonator/integrated circuit structure, the method comprising:
forming a piezoelectric layer on a surface of a growth substrate;
forming a first electrode on the piezoelectric layer;
forming a sacrificial layer overlapping the first electrode and the piezoelectric layer;
forming a support layer on the piezoelectric layer, the sacrificial layer and the first electrode;
providing an integrated circuit wafer including:
a substrate;
a plurality of first layers on the substrate, the plurality of first layers forming a front-end of line portion of the integrated circuit wafer having electronic semiconductor switching devices therein; and
a plurality of second layers forming a back-end of line portion of the integrated circuit wafer including ohmic conductors ohmically coupling regions of the electronic semiconductor switching devices to an outer one of the second layers of the integrated circuit wafer positioned opposite the electronic semiconductor switching devices;
bonding an upper surface of the support layer to an upper surface of the integrated circuit wafer to form a bonded interface therebetween;
processing the growth substrate to expose an upper surface of the piezoelectric layer that is covered by the growth substrate;
forming a first opening through the piezoelectric layer to expose the first electrode on a lower surface of the piezoelectric layer that is opposite the upper surface;
forming a first conductive layer on the upper surface of the piezoelectric layer and in the first opening to ohmically couple to the first electrode;
removing a portion of the first conductive layer to form a second electrode on the upper surface of the piezoelectric layer that is insulated from the first electrode and to form a first contact that is ohmically coupled to the first electrode;
forming a passivation layer on the upper surface of the piezoelectric layer to cover the second electrode and partially cover the first contact;
forming a second opening through the piezoelectric layer and through the support layer to expose at least one of the ohmic conductors included in the plurality of second layers forming the back-end of line portion of the integrated circuit wafer;
forming a second conductive layer to ohmically couple to the on the upper surface of the piezoelectric layer and in the second opening to ohmically couple the first electrode to at least one of the electronic semiconductor switching devices; and
removing the sacrificial layer.

2. The method of claim 1 wherein the electronic semiconductor switching devices included in the front-end of line portion of the integrated circuit wafer comprise CMOS transistors.

3. The method of claim 2 wherein the integrated circuit wafer further comprises:
a sealing layer on the plurality of second layers; and
a phosphate silicate glass layer on the sealing layer.

4. The method of claim 3 wherein bonding the upper surface of the support layer to the upper surface of the integrated circuit wafer is preceded by:
forming a SiO₂ bond layer on the phosphate silicate glass layer to provide the upper surface of the integrated circuit wafer.

5. The method of claim 3 wherein forming the support layer comprises forming a SiO₂ layer on the piezoelectric layer, the sacrificial layer and the first electrode.

6. The method of claim 3 wherein the phosphate silicate glass layer has a thickness in a range between about 1 um and about 3 um.

7. The method of claim 3 wherein the substrate comprises a Si substrate.

8. The method of claim 1 wherein the electronic semiconductor switching devices included in the front-end of line portion of the integrated circuit wafer comprise GaN HEMT devices, CMOS devices, power MOSFET devices, IGBT devices, HEMT devices, resistive memory devices, phase change materials, magnetic devices, and/or spintronic devices.

9. A method of forming a BAW resonator/integrated circuit structure, the method comprising:
forming a piezoelectric layer on a surface of a growth substrate;
forming a first electrode on the piezoelectric layer;
forming a multi-layered mirror structure on the first electrode;
forming a support layer on the piezoelectric layer, on the multi-layered mirror structure, and on the first electrode;
providing an integrated circuit wafer including:
a substrate;
a plurality of first layers on the substrate, the plurality of first layers forming a front-end of line portion of the integrated circuit wafer having electronic semiconductor switching devices therein; and
a plurality of second layers forming a back-end of line portion of the integrated circuit wafer including ohmic conductors ohmically coupling regions of the electronic semiconductor switching devices to an outer one of the second layers of the integrated circuit wafer positioned opposite the electronic semiconductor switching devices;
bonding an upper surface of the support layer to an upper surface of the integrated circuit wafer to form a bonded interface therebetween;
processing the growth substrate to expose an upper surface of the piezoelectric layer that is covered by the growth substrate;
forming a first opening through the piezoelectric layer to expose the first electrode on the lower surface of the piezoelectric layer;
forming a first conductive layer on the upper surface of the piezoelectric layer and in the first opening to ohmically couple to the first electrode;
removing a portion of the first conductive layer to form a second electrode on the upper surface of the piezoelectric layer that is insulated from the first electrode and to form a first contact that is ohmically coupled to the first electrode;
forming a passivation layer on the upper surface of the piezoelectric layer to cover the second electrode and partially cover the first contact;
forming a second opening through the piezoelectric layer and through the support layer to expose at least one of the ohmic conductors included in the plurality of second layers forming the back-end of line portion of the integrated circuit wafer; and
forming a second conductive layer on the upper surface of the piezoelectric layer and in the second opening to ohmically couple the first electrode to at least one of the electronic semiconductor switching devices.

10. A method of forming a MEMS/integrated circuit structure, the method comprising:
forming a piezoelectric layer on a surface of a growth substrate;
forming a first electrode on the piezoelectric layer;
forming a support layer on the piezoelectric layer and the first electrode;
bonding an upper surface of the support layer to an upper surface of an integrated circuit wafer to form a bonded interface therebetween, wherein the integrated circuit wafer includes:
a substrate;
a plurality of first layers on the substrate, the plurality of first layers forming a front-end of line portion of the integrated circuit wafer having electronic semiconductor switching devices therein; and
a plurality of second layers forming a back-end of line portion of the integrated circuit wafer including ohmic conductors ohmically coupling regions of the electronic semiconductor switching devices to an outer one of the second layers of the integrated circuit wafer positioned opposite the electronic semiconductor switching devices.

11. The method of claim 10 wherein forming the first electrode on the piezoelectric layer is followed by forming a sacrificial layer overlapping the first electrode and the piezoelectric layer, the method further comprising:
processing the growth substrate to expose an upper surface of the piezoelectric layer that is covered by the growth substrate;
forming a first opening through the piezoelectric layer to expose the first electrode on the lower surface of the piezoelectric layer;
forming a first conductive layer on the upper surface of the piezoelectric layer and in the first opening to ohmically couple to the first electrode;
removing a portion of the first conductive layer to form a second electrode on the upper surface of the piezoelectric layer that is insulated from the first electrode and to form a first contact that is ohmically coupled to the first electrode;
forming a passivation layer on the upper surface of the piezoelectric layer to cover the second electrode and partially cover the first contact;
forming a second opening through the piezoelectric layer and through the support layer to expose the upper surface of the integrated circuit wafer; and
forming a second conductive layer on the upper surface of the piezoelectric layer and in the second opening to ohmically couple the first electrode to at least one of the electronic semiconductor switching devices.

12. The method of claim 11 wherein the electronic semiconductor switching devices included in the front-end of line portion of the integrated circuit wafer comprise GaN HEMT transistors.

13. The method of claim 11 wherein the electronic semiconductor switching devices included in the front-end of line portion of the integrated circuit wafer comprise CMOS transistors.

14. The method of claim 13 wherein the integrated circuit wafer further comprises:
a sealing layer on the plurality of second layers; and
a phosphate silicate glass layer on the sealing layer.

15. The method of claim 14 wherein bonding the upper surface of the support layer to the upper surface of the integrated circuit wafer is preceded by:
forming a SiO₂ bond layer on the phosphate silicate glass layer to provide the upper surface of the integrated circuit wafer.

16. The method of claim 14 wherein forming the support layer comprises forming a SiO₂ layer on the piezoelectric layer, the sacrificial layer and the first electrode.

17. The method of claim 10 wherein forming the first electrode on the piezoelectric layer is followed by forming a multilevel mirror structure on the first electrode, the method further comprising:
processing the growth substrate to expose an upper surface of the piezoelectric layer that is covered by the growth substrate;
forming a first opening through the piezoelectric layer to expose the first electrode on the lower surface of the piezoelectric layer;
forming a first conductive layer on the upper surface of the piezoelectric layer and in the first opening to ohmically couple to the first electrode;
removing a portion of the first conductive layer to form a second electrode on the upper surface of the piezoelectric layer that is insulated from the first electrode and to form a first contact that is ohmically coupled to the first electrode;
forming a passivation layer on the upper surface of the piezoelectric layer to cover the second electrode and partially cover the first contact;
forming a second opening through the piezoelectric layer and through the support layer to expose the upper surface of the integrated circuit wafer; and
forming a second conductive layer on the upper surface of the piezoelectric layer and in the second opening to ohmically couple the first electrode to at least one of the electronic semiconductor switching devices.

18. A method of forming a BAW resonator/integrated circuit structure, the method comprising:
forming a piezoelectric layer on a surface of a growth substrate;
forming a first electrode on the piezoelectric layer;
forming a sacrificial layer overlapping the first electrode and the piezoelectric layer;
forming a support layer on the piezoelectric layer, the sacrificial layer and the first electrode;
providing an integrated circuit wafer including:
a substrate;
a plurality of first layers on the substrate, the plurality of first layers forming a front-end of line portion of the integrated circuit wafer having electronic semiconductor switching devices therein; and
a plurality of second layers forming a back-end of line portion of the integrated circuit wafer including ohmic conductors ohmically coupling regions of the electronic semiconductor switching devices to an outer one of the second layers of the integrated circuit wafer positioned opposite the electronic semiconductor switching devices;
bonding an upper surface of the support layer to an upper surface of the integrated circuit wafer to form a bonded interface therebetween;
processing the growth substrate to expose an upper surface of the piezoelectric layer that is covered by the growth substrate;
forming a second electrode on the upper surface of the piezoelectric layer that is insulated from the first electrode;
forming a passivation layer on the upper surface of the piezoelectric layer to cover the second electrode;
forming an opening through the piezoelectric layer and through the support layer to expose at least one of the ohmic conductors included in the plurality of second layers forming the back-end of line portion of the integrated circuit wafer; and
forming a conductive layer on the upper surface of the piezoelectric layer and in the opening to ohmically couple the first or second electrode to the at least one of the electronic semiconductor switching devices in the front-end of line portion of the integrated circuit wafer.
